(19) United States
(12) Patent Application Publication
(10) Pub. No.: US 2007/0153480 A1
(43) Pub. Date: Jul. 5, 2007

(54) MULTI-FLUID COOLANT SYSTEM

(75) Inventors: Chunbo Zhang, Plymouth, MN (US); Yuandong Gu, Plymouth, MN (US); Francis A. Kulacki, Edina, MN (US); Martin Kristoffersen, Maplewood, MN (US)

Correspondence Address: HONEYWELL INTERNATIONAL INC., 101 COLUMBIA ROAD, P O BOX 2245, MORRISTOWN, NJ, 07962-2245, US

(73) Assignee: HONEYWELL INTERNATIONAL INC., Morristown, NJ (US)

(21) Appl. No.: 11/612,241

(22) Filed: Dec. 18, 2006

Related U.S. Application Data
(60) Provisional application No. 60/751,506, filed on Dec. 19, 2005.

(51) Int. Cl. H05K 7/20; F25D 17/02

(52) U.S. Cl. 361/700; 62/185

(57) ABSTRACT

A system using a multi-fluid coolant. Immiscible or miscible fluids may be put through one or more channels. A device to be cooled may be thermally coupled to the channels. The boiling point of one fluid may be greater than an operating temperature that is to be maintained in the device. The boiling point of another fluid should be less than the operating temperature of the device.

This application claims the benefit of U.S. Provisional Application No. 60/751,506, filed Dec. 19, 2005. U.S. Provisional Application No. 60/751,506, filed Dec. 19, 2005, is hereby incorporated by reference.

### BACKGROUND

The present invention relates to cooling, and particularly it relates to cooling for electronic devices. More particularly, the invention relates cooling for microprocessors and other high transistor density devices.

### SUMMARY

The present invention provides a cooling approach having a several-component coolant.

### BRIEF DESCRIPTION OF THE DRAWING

FIGS. 1a and 1b are diagrams of a multi-fluid cooling system;

FIG. 2a shows a table listing cooling fluids and their physical properties;

FIG. 2b shows a table listing experiments some of which are discussed in the description;

FIGS. 3a and 3b are diagrams of a micro-cooler;

FIG. 4 shows a graph of Reynolds number in a micro channel versus a number of micro channels;

FIG. 5 shows a graph of the ratio Gr/Re² versus Re;

FIG. 6 shows the channel geometry of the micro-channel at the inlet and exit;

FIG. 7 shows a graph of pressure drop through a mini-cooler in terms of pressure drop versus a number of micro-channels;

FIG. 8 is a diagram of a heated channel base;

FIG. 9 shows a control volume layout for energy balance analysis;

FIG. 10 is a graph of the specific heats of water and a coolant versus temperature;

FIG. 11 is a schematic of an apparatus and its fluid flow;

FIG. 12 shows structural components of a channel;

FIGS. 13a , 13b and 13c show a channel without its end to display its walls;

FIG. 14 shows the channel with a removable cover;

FIGS. 15a and 15b show a length-wise and cross-section views of the removable cover, respectively;

FIGS. 16a and 16b show a cross section of the channel without the removable cover and with the cover, respectively;

FIG. 17 shows a diffusion block have beads for mitigating turbulent effect of a water inlet;

FIG. 18 shows a coolant vaporizer assembly having several plates fitted between acrylic components;

FIG. 19 shows the assembly of FIG. 18 with a cap and fitting;

FIG. 20 shows a strip heater placed against the plate on either side of the assembly of FIG. 18;

FIGS. 21a and 21b show an opening machined in into a channel cover to accept the coolant vaporizer assembly;

FIG. 22 shows a hole placement for thermocouples in a base plate;

FIG. 23 shows a base plate fitted into a channel;

FIG. 24 shows five individual heater blocks with 27 cartridge heaters installed

FIG. 25 shows a schematic of a cartridge heater and insertion to an opening of the heater block;

FIGS. 26a and 26b show grooves milled into the top of the heater block to provide clearance for thermocouples;

FIGS. 27a and 27b show a framework for clamping the heater blocks a channel bottom;

FIG. 28 shows a view of the channel assembly with various components;

FIG. 29 is a graph of water-only flow experiments in the channel assembly;

FIG. 30a is a diagram of a flow through a channel showing vaporized FC72 and condensed bubbles;

FIG. 30b is another depiction of the flow in FIG. 30a;

FIG. 31 shows a table of water and coolant properties where the coolant and water are mixed, for instance, in a tee-fitting upstream of a channel;

FIGS. 32, 33 and 34 show graphs of Nusselt number results for tee-fitting injection and liquid phase of coolant into the channel for various Reynolds numbers and heat flux into the channel;

FIGS. 35 and 36 show examples of a three-times scale copper device and a one-time scale copper device, respectively; and

FIG. 37 shows a three-times scale copper device with 45 degree side injection for pumped and pumpless approaches.

### DESCRIPTION

Many electronic devices have operating temperatures below 100 degrees C., especially silicon-based microprocessors, which have an allowable maximum temperature of about 75 to 95 degrees C. Although such devices have relatively low operating temperatures, they tend to generate significant heat. Therefore, there is a need to remove the heat from these components during their operation. It is generally recognized that as the processing speeds of these devices increase, so does their heat generation. Accordingly, the need to remove or dissipate heat from electronics becomes more critical as their processing speeds increase.

The increased heat dissipation requirements of electronics mandate active cooling methods. An active cooling method is liquid cooling. Of the various liquid coolants available, water is regarded as the best and most convenient in terms of heat transfer coefficients. Additionally, it is generally recognized that two-phase flow heat transfer is good due to its high heat flux cooling. Achieving two-phase flow may be difficult, however, since water cannot vaporize below 100 degrees C. unless it is in a low pressure environment. A low pressure environment, however, requires hermetic packaging which tends to be prohibitively expensive. Therefore, there is a need to promote two-phase cooling under normal (atmospheric) pressure and below 100 degrees C. The present invention fulfills this need among others.

The present invention provides for an effective two-phase cooling approach by using a two-component coolant. Specifically, by using a two-component coolant in which one component has a relatively low boiling point compared to the other component, two-phase cooling can be readily achieved under normal pressure, thereby avoiding the need for hermetic or other complicated packaging techniques. For example, a mixture of water and a low boiling point coolant such as FC-72 (available from 3M) can be used to achieve two-phase flow heat treatment and facilitate better heat exchange than a single-phase coolant (e.g., water) alone. In the coolant, water serves as the major heat carrier due to its excellent heat transfer coefficient and heat capacity. On the other hand, the low boiling point coolant vaporizes at a relatively low temperature below the maximum safe operating temperature of the device being cooled. The vaporization process, and thereby the introduction of bubbles inside the coolant, may generally enhance heat transfer to the coolant. Also, the heat transfer could be improved by more that two times that of a single-phase water coolant. However, in some tests the improvement might be only 5 to 10 percent. It may be noted that “fluid” can mean a “liquid” or a “gas”.

Furthermore, if the low boiling point coolant and water are immiscible, as in the case of, for example, water and FC-72, further heat transfer enhancement can be obtained by using a porous media. Incidentally, in other examples, other fluids, such miscible fluids may be used. Hydrophobic porous media can be used in the sidewalls of the flow channels to adsorb FC-72 and not to let water in. The porous media facilitate the boiling of FC-72 at a small excess temperature above its boiling point. The hydrophobic porous media can also be used to supply FC-72 to the hot boiling regions, as in heat pipes. For cooling applications in small devices or high heat flux devices, the flow channels may be micro or mini channels that generally provide higher heat transfer than larger channels.

Although in one illustrative example water is the main heat carrier, the main heat carrier of the present invention of coolant compositions is not limited to water. Other coolants with high heat transfer coefficients but higher boiling points than the maximum allowable temperature can be used as the main carrier to achieve a two-phase flow heat transfer for high heat flux applications.

One aspect of the invention is a two-component, two-phase coolant composition for cooling a device having a maximum allowable operating temperature. In an illustrative example, the coolant may have a first component having a boiling point above said maximum allowable operating temperature at normal pressure, and a second component having a boiling point below said maximum allowable operating temperature at normal pressure. The first component may have a heat capacity greater than that of the second component, and the second component may be immiscible in the first component. Although, in some instances, the second component may be miscible.

Another aspect of the invention is a process for cooling a device having a maximum allowable operating temperature using a two-component, two-phase coolant. In an illustrative example, the method comprises effectively contacting said electronic device with a coolant comprising a first component having a boiling point above said maximum allowable operating temperature at normal pressure, and a second component having a boiling point below said maximum allowable operating temperature at normal pressure. The second component may be injected as a vapor into a fluid flow of the first component.

Description showing the viability of using a binary coolant comprising water and FC-72 to cool electronic devices is provided herein. It should be recognized that aspects of the present invention are not limited to the present description and that additional benefits and advantages of the invention are likely to be recognized through additional research. Furthermore, it should be understood that, although a coolant comprising effective portions of water and FC-72 is considered herein; other binary or multiple coolant compositions may be contemplated within the scope of the invention.

A rectangular channel has been designed and constructed to investigate single-phase and two-phase heat transfer and fluid flow. The working fluid is a combination of water and FC-72, a fluorinated substance. The addition of FC-72 to the water stream may produce an enhanced heat transfer effect compared to water-only flow. Flow visualization and heat transfer experiments may be conducted at temperatures below the boiling point of water so the water remains in the liquid phase. The FC-72 may exist in both the liquid and vapor phases.

The side walls of the channel may be constructed of glass for flow visualization. The remaining sides may be machined out of acrylic. The roof of the channel may be designed to provide a nearly adiabatic boundary and to be removable to accommodate future modifications to the aspect ratio of the channel. Aluminum blocks may be embedded with cartridge heaters and may be fitted into the channel base to provide a constant heat flux boundary.

It may be concluded that the use of a two fluid cooling stream, water and FC-72, offers significant cooling advantages when compared to water-only flow in the test apparatus. Nusselt numbers with FC-72 injection could be approximately twice those of water-only flow.

Conventional cooling of computers and other electronic equipment appears inadequate for the technologies of the future. The continued miniaturization of computer chips, the development of advanced lasers, and the general evolution of technology may require devices that provide cooling that is superior to what appears currently available. The present invention may include a channel designed to examine the cooling potential of a two-component stream. Specifically, water is mixed with a fluorinated chemical and the heat transfer coefficient and Nusselt number may be determined.

Cooling through the use of pool boiling may involve sealing the CPU in a chamber filled with a dielectric fluid. Heat from the chip causes the fluid to boil. Vapor may rise to the top of the chamber, where it condenses, and sinks back to the bottom. Pool boiling has the potential to achieve large heat transfer rates due to the phase change of the dielectric fluid, but a major problem of implementing this type of cooling system is that it is orientation-sensitive. For example, pool boiling might not be an effective means of cooling such things as laptop computers because the natural convection of the dielectric fluid depends on gravity and on the orientation of the computer.

Heat pipes may consist of a container filled with a liquid working fluid. The internal surface of the container is covered in a layer of porous material. Capillary forces draw the fluid into the pores of the material. When heat is applied at any point along the surface of the heat pipe, liquid at that point boils and enters the vapor state. The higher pressure of the vaporized liquid drives it to a colder location inside the container, where it condenses. In this way, the heat pipe may rapidly move heat from one location to another.

The effective thermal conductivity of heat pipes is many thousands of times that of copper; however, an external heat exchanger is necessary. In addition, the volume of the working fluid that can be contained within the porous material is limited, so heat pipes appear not to be feasible for high power applications.

A more effective means of cooling may be through the use of single-phase liquid-cooled heat sinks. An array of parallel micro-channels may be mounted on top of the chip and a pump be used to force cooling fluid through the channels. This type of cooling may be more effective than with air-cooled heat sinks due to thermal properties of fluids compared to those of gases. After exiting the micro-channels, the heated fluid may be cooled through the use of an external heat exchanger.

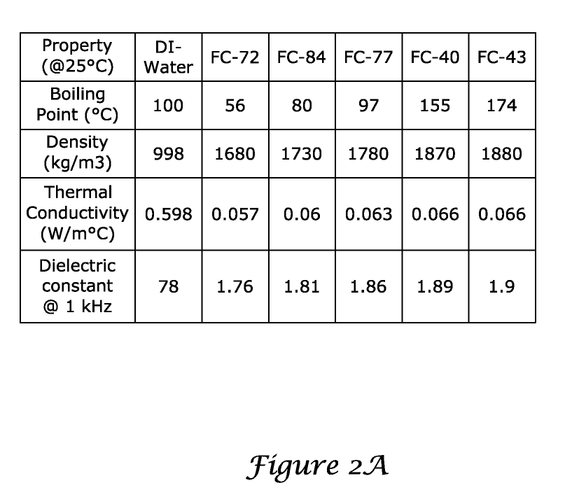

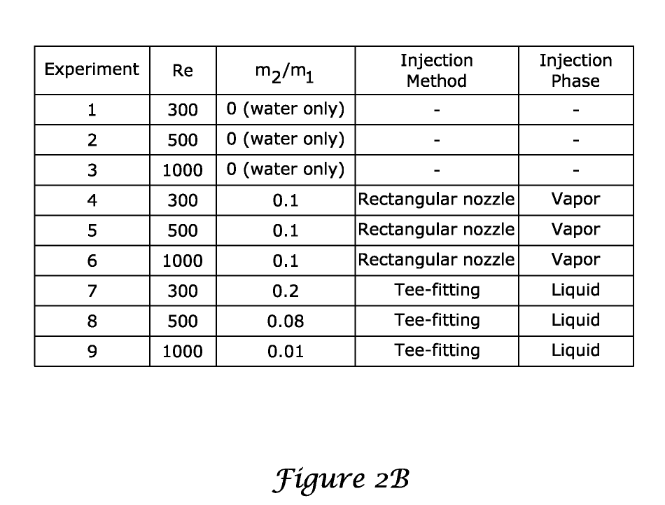

The invention may involve two-phase working fluids which offer great cooling advantages relative to single-phase liquids and phase change within the micro-channels results in large heat transfer coefficients. The cooling capability of two-phase forced-convection in micro-channels indicates that significant potential exists. If the properties of the secondary fluid are such that it changes phase at lower temperatures than water, then large heat transfer coefficients at lower temperatures may be possible. An approach is that water will flow through the micro-channels at sub-cooled temperature. Droplets of the secondary fluid, mixed in with the water stream, will also flow through the micro-channels. Upon contact with the hot surfaces or hot-enough water near the surfaces in the micro-channels, the secondary fluid will boil and change to vapor. As the vapor mixes with the cold water it will condense, transferring heat to the water. The now-liquid secondary fluid will flow downstream until it again meets the channel walls or hot-enough water near the walls, where the cycle will repeat. In this manner, the heat transfer between the micro-channel wall and the water will be enhanced. For this approach, a fluid with a lower boiling point than water is desired because this particular cooling application may require that the surface of the computer chip be maintained at 95 degrees C. or less. This precludes the use of water only for the cooling fluid at room pressure since two-phase flow would be impossible at such low temperature at atmospheric pressure. Physical properties of various fluorinated chemicals (i.e., Fluoinet™ liquids) available from 3M are listed in a table in FIG. 2a . The properties of boiling point, density, thermal conductivity and dielectric constant for water, FC-72, FC-84, FC-77, FC-40 and FC-43 may be noted in the table. Of the chemicals in the table, FC-72 possesses the lowest boiling point. These chemicals may be looked at and FC-72 selected as an illustrative example. Other fluids may be appropriate as a secondary fluid to be mixed with water or another fluid in the present invention. Other fluids may include other fluorocarbon coolants, and Genetron 245FA having a low boiling point of about 15 degrees C. at one atmosphere.

The fluids may be miscible, as long as boiling can happen at a low temperature in one atmosphere, the low temperature being the maximum temperature of the item being the subject of cooling. There may be multiple fluids (i.e., including more than two fluids, miscible or immiscible) so long as at least one fluid has a boiling point lower than maximum allowable for desired cooling purposes. The cooling operation with the fluids may involve two or more phases.

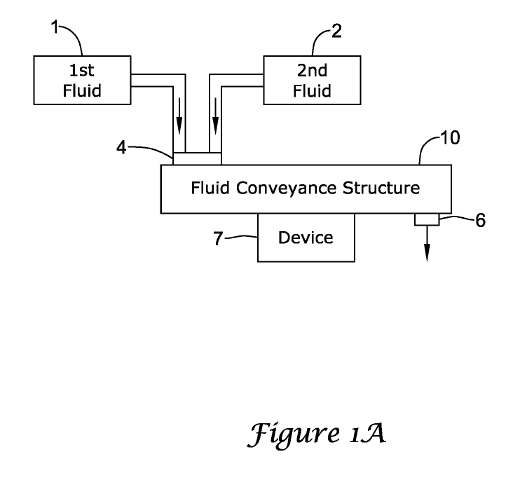

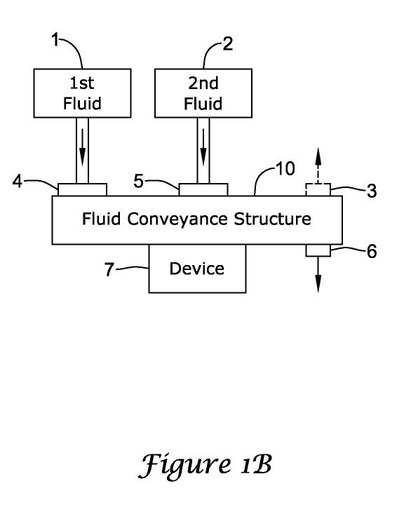

FIGS. 1a and 1b show illustrative examples of the invention. FIG. 1a shows a first fluid supply which may provide a fluid 1 to an inlet 4 of a fluid conveyance structure 10. A second fluid supply may provide a fluid 2 to the fluid conveyance structure 10 at inlet 4. They may flow through a structure 10 to cool down a device 7 which is thermally coupled or connected to structure 10. The fluids 1 and 2 may exit structure 10 at an outlet 6, or from separate outlets (as shown in FIG. 1b). The fluids 1 and 2 may be in a liquid phase and come together as the enter structure 10 via inlet 4. Fluid 2 may instead be a vapor or in a gas phase when entering inlet 4. Or, fluids 1 and 2 may enter structure 10 in various combinations of phases. There may also be additional inputs for various kinds of fluids of different states. There may also various other configurations for outputs. FIGS. 1a and 1b show illustrative examples of two configurations.

FIG. 1b shows a first fluid supply providing a fluid 1 to inlet 4 of the fluid conveyance structure 10. A second fluid supply may provide a fluid 2 to another inlet 5 of structure 10. Inlet 5 may be downstream from inlet 4. Fluid 1 may enter inlet 4 in a liquid phase. Fluid 2 may enter inlet 5 as a vapor or in a gas phase. However, fluids 1 and 2 may enter the structure 10 in various combinations of phases. The fluids 1 and 2 may exit structure 10 together from the outlet 6, or separately from outlets 6 and 3, respectively.

The fluid conveyance structure 10 in FIGS. 1a and 1b may have different locations for the inlets and outlets other than shown. Device 7 may be thermally coupled or connected to structure 10 in ways not shown. Structure 10 may effectively be a heat sink for device 7.

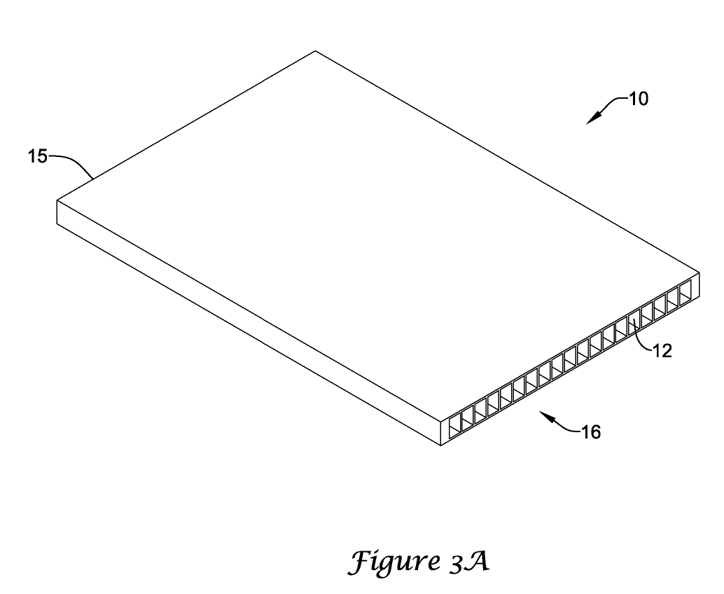

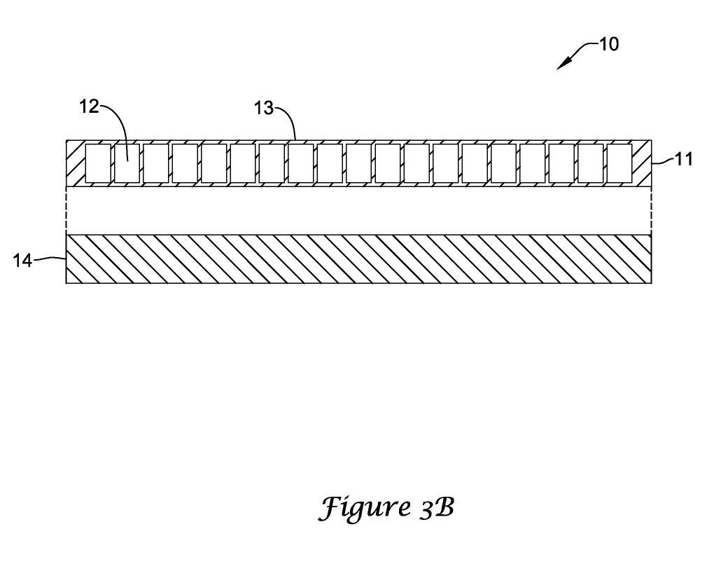

Structure 10 may have one or more micro/mini channels. FIGS. 3a and 3b show an illustrative pattern. Structure 10 may be some other kind of conveyance type of structure such as some porous material, capillary tubing, or the like.

Fluids 1 and 2 may have different properties. The fluids may be immiscible or miscible, have different boiling points, different heat transfer coefficients, and different heat capacities.

It is a desire to keep the temperature of device 7 below a particular operating temperature. Device 7 may be a processor on a chip or some other mechanism. Device 7 may generate heat while operating. If device 7 is not provided some cooling, it may overheat and fail operationally. The present invention is designed to provide effective cooling of device 7 with the two or more fluid or component fluid approach provided herein.

In the illustrative examples of FIGS. 1a and 1b , and other Figures and description herein, there may be two or more different fluids in one or more phases. As an illustrative example for fluids 1 and 2, one may select a fluid 1 that has a boiling point higher than the operating temperature of device 7 or other heating mechanism thermally connected to structure 10. A fluid 2 having a boiling point below the operating temperature may be selected. An example of fluid 1 may be water. An example of a fluid 2 may be a halogenated or fluorinated compound. For illustrative purposes, a fluorinated compound such as FC-72 with properties shown in the table of FIG. 2a may be selected. An operating temperature of device 7 and the portion of structure 10, working as a heat sink for the device, may be considered to be between 70 and 95 degrees Celsius, which could be that of a silicon processor chip having a high density of transistors. For the present example, it may be noted that the boiling point of water and FC-72 are above and below the operating temperature, i.e., 100 and 56 degrees C., respectively. Depending on the particular coolant, a cooled to temperature may range from 45 degrees C. to 95 degrees C.

Further description, modeling and analyses provided herein demonstrate the operation of the present invention.

One may note whether the injection of FC-72 into a primary cooling stream of water will enhance the overall heat transfer capabilities of the channel and resultant cooling. The mixing behavior of the FC-72 and the water may be observed and characterized. To study the flow in the micro-cooler, a scaled up version of a single micro-channel may be used. Tests may be performed using this scaled-up channel to determine heat transfer and fluid flow characteristics. The information gathered in these tests provides insight into the effects of using a two-fluid stream (FC-72 and water) as a cooling fluid. One objective is to investigate several different mixing conditions, and where possible obtain heat transfer coefficients for a range of flow conditions. Mixing of liquid-liquid and liquid-vapor flows within the channel may be examined.

The table of FIG. 2b shows a summary of experiments 1-9, some of which are noted herein. The mass flow of the water is m₁ and the mass flow of the FC-72 is m₂. The experiments calling for vapor injection of FC-72 may be performed with bulk fluid temperatures that are above the saturation temperature of FC-72. Experiments with liquid FC-72 may have inlet temperatures less than the saturation temperature of FC-72. Flow visualization data is studied and temperature data is obtained for various ratios of FC-72 and water.

Two methods of FC-72 injection are examined. In the first method, FC-72 is vaporized and then injected through an angled rectangular inlet nozzle (experiments 4-6). In the second method, liquid FC-72 and water are combined upstream of the channel inlet in a simple tee-fitting (experiments 7-9).

One may vary the aspect ratio of the channel (width relative to height). In addition to uniform heat flux, hot-spot testing may be of interest. Heating may occur through the use of a single heater element, with no conduction down the length of the channel. The design and construction of the test channel attempts to satisfy these requests while not compromising the primary objectives.

The test flow channel may mimic the characteristics of a single micro- or mini-channel oft, for example, 0.04×0.05×1 cm. Micro-channels may have 200×200 micron cross-sections with 200 micron spacing. These channels may be MEMS-sized devices. Smaller channels such as those of a nano range may be implemented for cooling, and the description herein may be relevant to it. Larger channels may be three to 100 times larger, or more, than the micro-channels. Mini-channels may be just several times larger than micro-channels. An example design may have a maximum 22 channel 500×400 micron, 200 micron spacing (about 1.5 cm total width for channel region) design. Dimensionless parameters have been determined for a micro-heat exchanger 10 (see FIGS. 3a and 3b for an illustration of a micro-cooler 10 and an end view of the cooler) for various flow conditions and the large-scale test channel may be constructed to emulate these parameters. The micro-cooler 10 may have a silicon wafer 11 with parallel channels 12 etched into it and a silicon plate cover 13, thus forming a series of enclosed rectangular ducts. Coolant may pass through the channels 12 for providing cooling to, for example, a CPU chip 14 below the silicon wafer 11. Details regarding flow through the micro-heat exchanger 10 may be examined as part of a design process of a large-scale apparatus. The overall volumetric flow rate through the micro-heat exchanger (the flow through all of the micro-channels 12 combined) may be set at 200 mL/min. This information, as well as channel 12 height, width, and length, may be used to determine the flow parameters.

When a large scale test channel is constructed, certain flow parameters for the actual micro-cooling device 10 may be calculated. The overall volumetric flow rate has been specified as 200 mL/min. It may be assumed that this flow is uniformly divided between all of the channels 12. The average fluid velocity is,

$$V = \frac{\dot{Q} v}{n A} , \qquad ( 1 )$$

where V is the average fluid velocity through the micro-cooler 10, Qᵥ is the overall volumetric flow rate, n is the number of channels, and A is the cross-sectional area of each micro-channel 12.

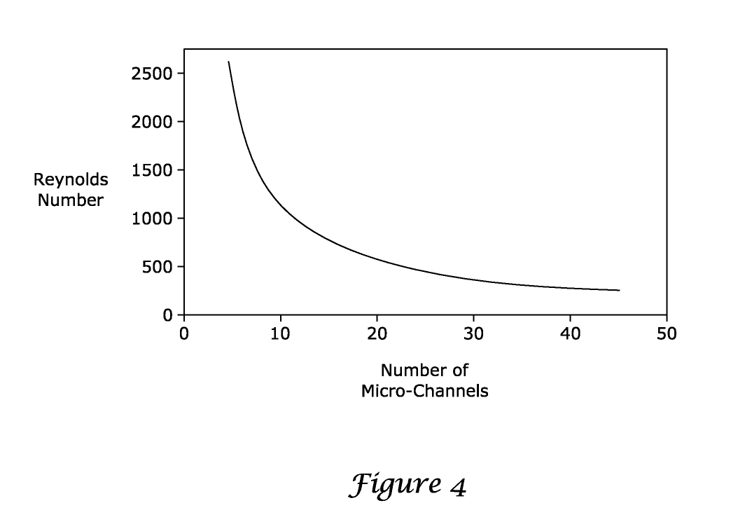

The Reynolds number may provide a measure of the ratio of the inertial to viscous forces acting on a fluid element. The large scale apparatus may be designed to have the same Reynolds number as the smaller micro-channel 12. The Reynolds number (Re) is,

$$Re = \frac{ρ {VD}_{H}}{μ} , \qquad ( 2 )$$

where D_{H} is the hydraulic diameter, ρ is the density of the fluid, and μ is the dynamic viscosity of the fluid. The hydraulic diameter of the micro-channel 12 is,

$${D}_{H} = \frac{4 A}{P} , \qquad ( 3 )$$

where P is the wetted perimeter. The Reynolds number as a function of the number of channels 12 is shown in the graph of FIG. 4. Flow may be assumed to be equally distributed among all channels. Qᵥ=200 mL/min and D_{H}=500 μm.

The test apparatus may emulate the parameters of the micro/mini cooler 10. The number of channels 12 in the micro-cooling device 10 may be between 10 and 30, with the hydraulic diameter of 500 μm. In the graph of FIG. 4, the large apparatus may be designed to examine Reynolds numbers from 500 to 1300.

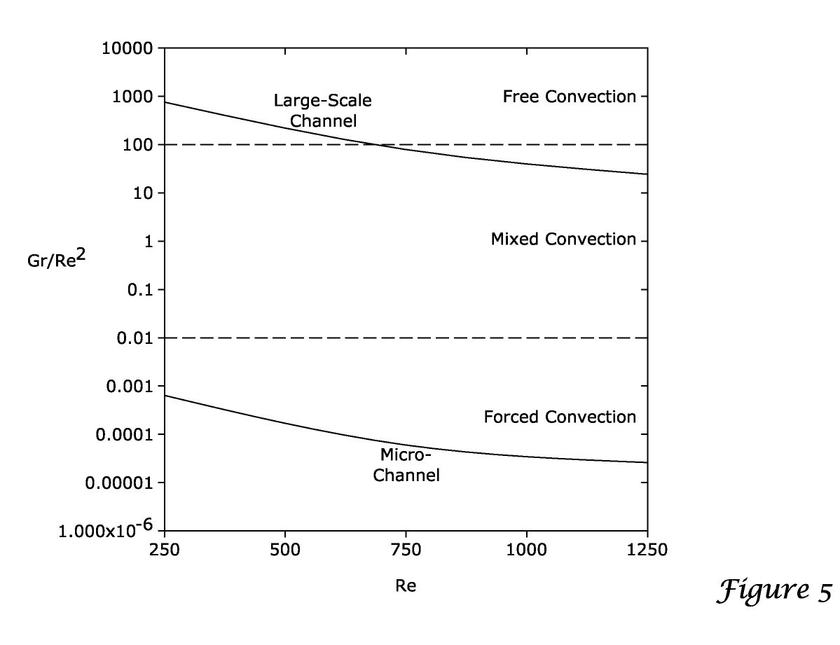

Another consideration in attempting to go from micro-scale to large-scale dimensions (an increase in hydraulic diameter of 100 times) is the Grashof number, Gr. The Grashof number indicates the ratio of the buoyancy force to the viscous force acting on the fluid. A dominant mechanism of heat transfer within the channel may be determined by examining the Grashof and Reynolds numbers. The ratio Gr/Re² may be used to determine whether forced or free convection is the dominant form of heat transfer. For the actual micro-channel 12, forced convection appears to dominate, while in the large-scale channel, both forced and free convection may be considered. The Grashof number is defined as,

$$Gr = \frac{g β ( {T}_{W} - {T}_{B} ) {D}_{H}^{3}}{{v}^{2}} , \qquad ( 4 )$$

where g is the gravitational constant, ν is the kinematic viscosity, T_{w} is the temperature at the channel wall, T_{B} is the average temperature of the fluid, and μ is the isobaric thermal expansion coefficient. The isobaric thermal expansion coefficient provides a measure of the amount by which the density changes in response to a change in temperature at constant pressure. The thermal expansion coefficient, β, is defined as,

$$β = - \frac{1}{ρ} \frac{\partial ρ}{\partial T} , \qquad ( 5 )$$

where ρ and T are the density and the temperature of the fluid, respectively. Equation (5) may be approximated by,

$$β \approx - \frac{1}{{ρ}_{W}} \frac{{ρ}_{B} - {ρ}_{W}}{{T}_{B} - {T}_{W}} , \qquad ( 6 )$$

where ρ_{B} is the bulk fluid density and p_{w} is the fluid density at the wall. Because the Grashof number depends on the cube of the hydraulic diameter, there may be some difference between the large scale test channel and the actual scale micro heat-exchanger 10. If Gr/Re²<<1, the free convection effects may be neglected. Conversely, if Gr/Re²>>1, then forced convection effects may be neglected. The Grashof number for the micro-channel 12 is such that forced convection dominates because the hydraulic diameter of the micro-channel is on the order of 500 μm, which ensures a small Grashof number. This is not necessarily the case for the large scale apparatus. The scaled-up hydraulic diameter may be about 100 times larger than the actual micro-channel 12 hydraulic diameter. When this dimension is cubed, the Grashof number for the large scale apparatus may be found to be one million times larger than that of the actual micro-channel. Thus, free and forced convection both must be considered in the large-scale apparatus. Predicted forms of heat transfer for the micro-channel 12 and the large-scale channel are shown in the graph of FIG. 5. In this graph, where Gr/Re² versus Re is shown, the ratio of Gr/Re² may determine the dominant mechanism of heat transfer. For Gr/Re²<<1, forced convection effects appear dominant. For Gr/Re²>>1, natural convection appears dominant. For Gr/Re²≈1, both forced and natural convection should be considered. A temperature difference of T_{w}−T_{B}=30 degrees C. may be assumed in developing this graph.

The pressure losses through the micro-channels 12 may be predicted and the pressure drop through the large-scale apparatus can be estimated. The pressure drop through the micro-cooler 10 may be from three sources. There may be frictional losses as the fluid passes along the channel 12 walls, minor losses due to the sudden contractions as the fluid enters the channel 12 at an inlet 15, minor losses as the fluid experiences sudden expansion at the channel exits 16. The overall pressure drop may be the sum of the three,
Δpₜₒₜₐₗ=Δp_{wall}+Δp_{entrance}+Δpₑₓᵢₜ. (7)

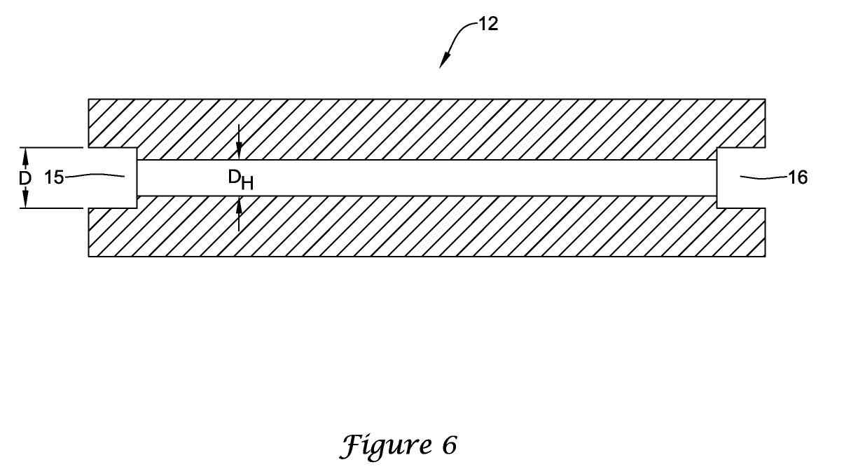

The pressure drop calculation presented herein may assume that the fluid flow is uniformly distributed to all of the micro-channels 12. In addition, the average fluid velocity is assumed to be constant as the fluid flows from the inlet 15 plenum, through the micro-channel 12, and through the exit 16 plenum. FIG. 6 shows the channel geometry of the micro-channel 12 at the inlet 15 and exit 16. The height at the channel 12 inlet and exit is D. D_{H} is the channel hydraulic diameter. The fluid velocity may be less in the larger areas of the inlet and outlet plenums. But in the absence of any specific numbers regarding the geometry of these sections, a conservative estimate may be made. By assuming a higher velocity in the inlet and outlet plenums, the calculation may result in a higher pressure drop and errors should be on the conservative side.

The overall volumetric flow rate may be specified as Qᵥ=200 mL/min, but the number of channels 12 is not yet determined. Because of this, the pressure drop estimate presented here is given as a function of the number of channels. As the number of channels 12 increases, the flow through each will decrease, and the average fluid velocity through each channel will also decrease. Forcing the same flow through fewer channels will result in higher average velocity, and will produce a higher pressure drop.

An expression for frictional and minor losses through a duct of any cross-sectional area is,

$$Δ p = \frac{ρ {V}^{2}}{2} ( f \frac{L}{{D}_{H}} + {\sum }_{i} {K}_{i} ) , \qquad ( 8 )$$

where Δp is the pressure drop due to fictional and minor losses, L is the micro-channel length,

$${\sum }_{i} {K}_{i}$$

is the sum of all minor loss coefficients, V is the mean velocity of the flow, and f is the Darcy friction factor. The density, p, is evaluated at average fluid conditions. Equation (8) appears valid for duct flows of any cross sectional area and for laminar and turbulent flow. A correlation for the Darcy friction factor for fully developed laminar flow is,

$$f = \frac{64}{Re} . \qquad ( 9 )$$

Equation (9) should not be confused with the Fanning friction factor. The Darcy friction factor is four times the Fanning friction factor. The pressure drop estimate may be made by assuming that the flow will be evenly distributed through n channels. The average fluid velocity may be determined from equation (1).

The fluid may experience a sudden contraction at each of the micro-channel 12 inlets 15 when it moves from the plenum at the entrance to the narrower diameter of the micro-channels (FIG. 6). The loss coefficient associated with each of these sudden contractions is,

$${K}_{SC} = 0.42 ( 1 - {( \frac{{D}_{H}}{D} )}^{2} ) , \qquad ( 10 )$$

where D is the height of the plenum at the entrance of the channel. Equation (10) is an empirical formula, and may be valid for D_{H}/D<0.76.

The fluid may experience a sudden expansion as it exits each of the micro-channels 12. The loss coefficient for these sudden expansions is,

$${K}_{SE} = {( 1 - {( \frac{{D}_{H}}{D} )}^{2} )}^{2} . \qquad ( 11 )$$

Equation (11) is a theoretical expression based on a control volume analysis (not presented here), which appears to agree well with experimental data.

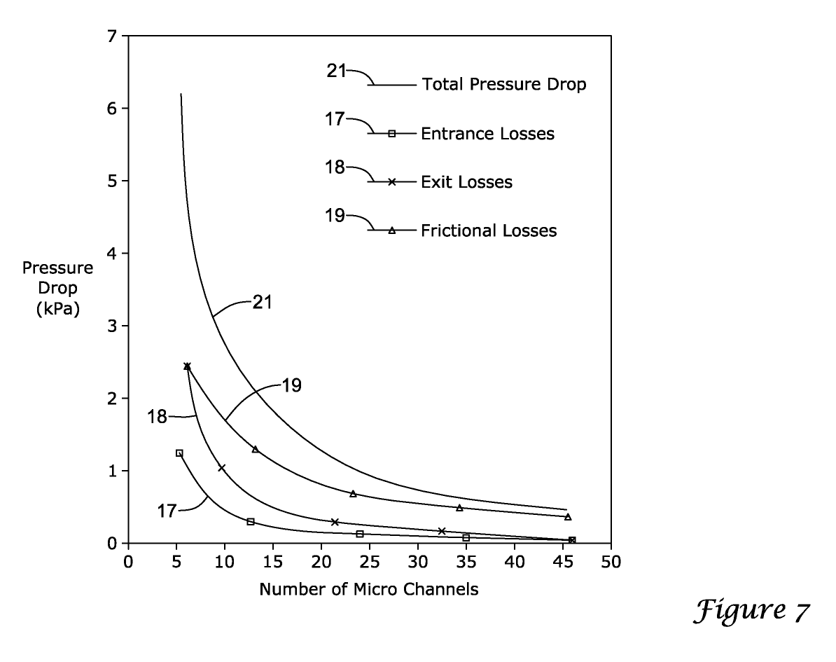

For simplicity, the flow through the micro-cooler 10 is assumed to be fully developed and laminar. The full expression for all of the losses through a single micro-channel 12 is,

$$Δ {p}_{total} = \frac{ρ {V}^{2}}{2} ( f \frac{L}{{D}_{H}} + {K}_{SC} + {K}_{SE} ) , \qquad ( 12 )$$

where, for between 10 and 30 channels, the pressure drop through the micro-cooling device 10 may be expected to be between 1 and 3 kPa. A graph of FIG. 7 shows pressure drop (kPa) versus a number of micro channels 12. This graph shows the total pressure drop 21 through the micro-cooler 10. Entrance 15 losses 17, exit 16 losses 18, and losses due to wall friction 19 are also shown. The overall volumetric flow rate is 200 mL/min. As can be seen in FIG. 7, frictional losses 19 appear as the main source of the pressure drop in the micro-channel 12. The minor losses at the entrance 15 and exit 16 of the channels account for approximately 25% of the total pressure drop. This estimate of the pressure drop in the micro-channel 12 may provide what to expect when the dimensions are scaled up.

As can be seen in equation (12), frictional losses are dependent on the fluid velocity. The velocity in the large-scale apparatus will be much less than in the micro-channel 12 for a given Re and therefore the pressure drop in large-scale channel will be less than 2 kPa. This is an insignificant pressure drop and so pressure losses in the large scale apparatus may be neglected.

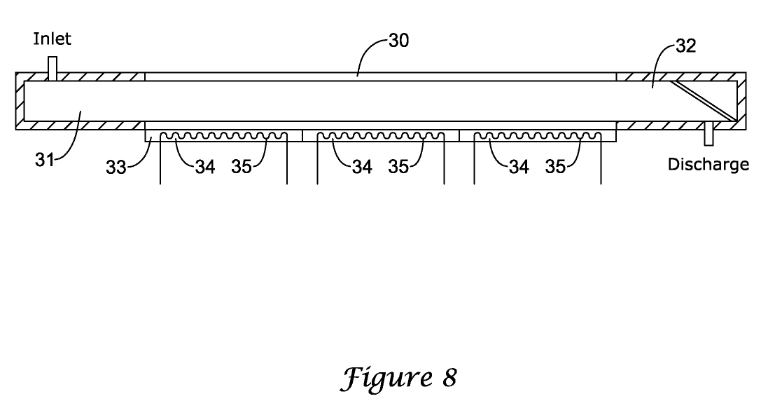

A cross-section of a large-scale heated channel 30 base 33 is shown in FIG. 8. Fluid may enter at one end 31, pass over the heated base 33, and exit at the other end 32. The heated channel base 33 may be made up of three individual heater blocks 34, each with nine cartridge heaters 35. There may be more or less blocks and cartridge heaters. Each heater block is powered and controlled from a different circuit. This design may result in some variation in the power provided by each heater block 34, but the voltages available from each circuit may be within three percent of each other.

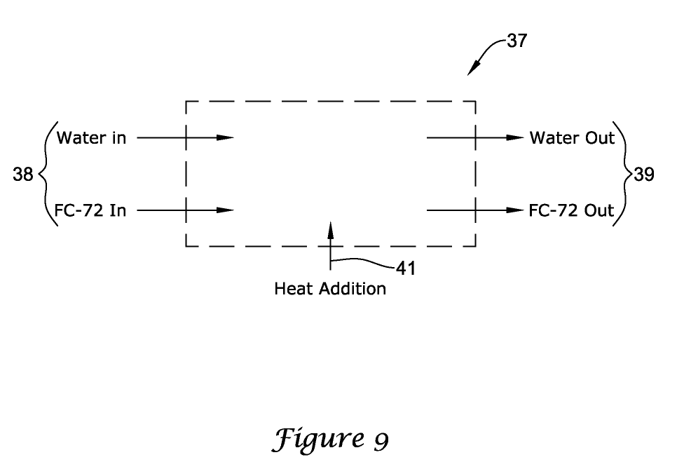

The ideal power input to each heater block may be calculated based on the number of cartridge heaters 35 per block 34 and the power setting. If there were no losses, then all of this power should enter the channel 30. This generally is not the case. An estimate of the losses may be made by comparing the actual power input to the ideal power input. The power input from each of the three heater blocks 34 may be determined by performing an energy balance on the system. A control volume layout 37 is depicted in FIG. 9, with water and FC-72 in and water and FC-72 out, and the addition of heat. The difference between the heat in the water and FC-72 at the in part 38 and out the part 39 may be measured and the difference may be compared to the heat addition 41 to determine heat loss by the channel.

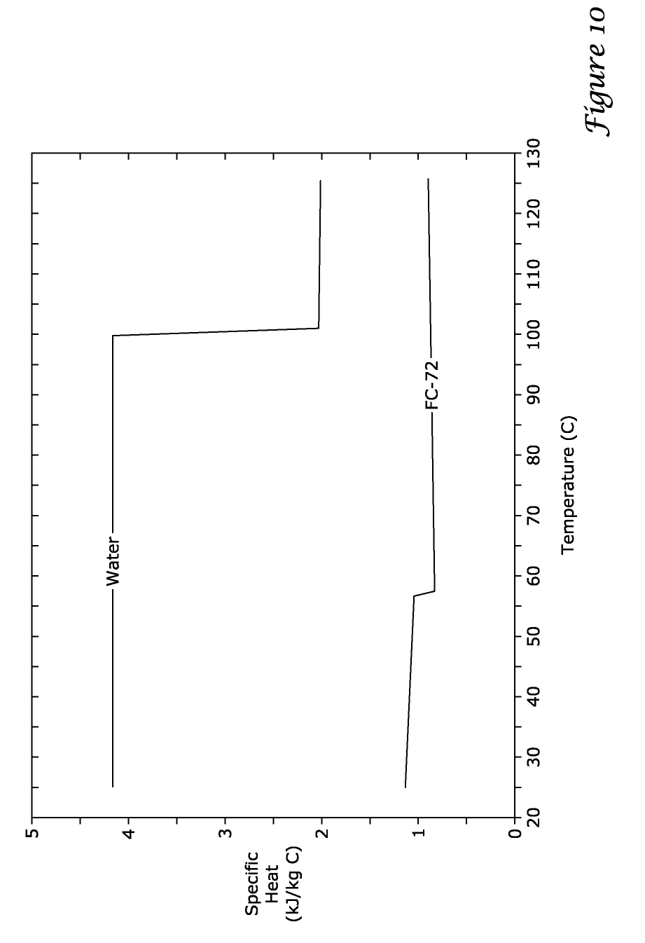

The energy balance for the system 37 is,

$$\frac{ⅆ U}{ⅆ t} = \dot{Q} - \dot{W} + {\sum }_{Out} \dot{m} ( h + \frac{{V}^{2}}{2} + gz ) - {\sum }_{in} \dot{m} ( h + \frac{{V}^{2}}{2} + gz ) , \qquad ( 13 )$$

where Q is the heat transfer rate across the boundary, W is the work transfer rate across the boundary, U is the internal energy, h is enthalpy, and z is height. Steady flow, steady state conditions are assumed. It is also assumed that no work takes place and that changes in bulk kinetic and potential energy are negligible. With these assumptions, equation (13) reduces to,
Q=(mh)_{water,in}+(mh)_{FC72,in}−(mh)_{water,out}−(mh)_{FC72,out} (14)
or
Q=[mcₚ(Tₒᵤₜ−Tᵢₙ)]_{water}+[m(cₚTₒᵤₜ−cₚTᵢₙ)]_{FCη} (15)
A graph of FIG. 10 shows the specific heats (kJ/kg C) of water and FC-72 as a function of temperature (C). Phase changes for water and FC-72 may be noted. As can be seen in the graph, the specific heat of water is constant for these temperatures (40 degrees C. to 60 degrees C.), but through this range the specific heat of FC-72 drops as the fluid changes phase.

The inlet 38 and outlet 39 temperatures of the water may be measured of layout 37. The inlet and outlet temperatures of the FC-72 are considered to be the same as the inlet and outlet temperatures of the water because the two fluids are in intimate contact. The losses may be estimated by comparing the applied power input 41 supplied by the heater blocks 34 to the actual increase in energy as calculated determined by the energy balance. The power supplied may vary from 400 W to 800 W, depending on the experimental run.

For simplicity, it is assumed that the actual power input to the channel 30 is evenly spread over the three heater blocks 34. In other words, the power input to the channel from each of the three heater blocks is,

$$\frac{{Q}_{actual}}{3} , \qquad ( 16 )$$

where Q_{actual} is the actual power which enters the channel 30, as determined by equation (15). The losses for each heater block 34 are determined by,

$${\dot{Q}}_{loss} = {\dot{Q}}_{e} - \frac{{Q}_{actual}}{3} , \qquad ( 17 )$$

where Qiₗₒₛₛ is the power loss. The applied power input for the each heater block is Qₑ. The voltage from each circuit is known and the resistance of each heater 35 is known, therefore Qₑ can be determined for each heater block 34. A revised heat input estimate may be made to determine the power actually transferred into the channel 30.
Q_{revised}=Qₑ−Qₗₒₛₛ (18)
For the experimental runs noted so far the losses have been about 50 percent of the applied power, so the heat input 41 into the channel base is between 200 W and 400 W. Improved insulation should hopefully limit losses in future runs.

The heat transfer coefficient is given by
Q_{revised}=hA(T_{w}−T_{b}), (19)
where h is the heat transfer coefficient, A is the area of the heated section, T, is the channel 30 wall temperature, and T_{b} is the bulk temperature of the fluid. The average wall and bulk temperatures may be taken for each of the heater blocks 34 and the heat transfer coefficient be calculated based on these averages. The Nusselt number is,

$$Nu = \frac{{hD}_{h}}{k} , \qquad ( 20 )$$

where k is the conductivity of the fluid. The Nusselt number is typically plotted as a function of 1/Gz, where the Graetz number is,

$$Gz = \frac{{D}_{h}}{x} RePr . \qquad ( 21 )$$

In equation (21), x is the distance along the channel 30 and Pr is the Prandlt number ν/α, where ν is the kinematic viscosity and α is the thermal diffusivity of the fluid). Here, Re and Pr may be evaluated at the average bulk temperature of the fluid,

$${T}_{B , avg} = \frac{{T}_{in} + {T}_{out}}{2} . \qquad ( 22 )$$

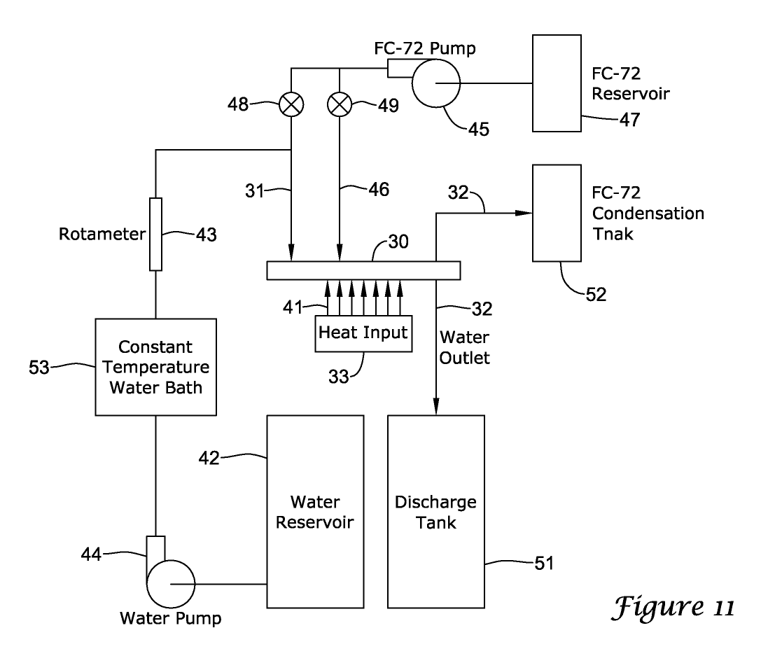

The channel 30 may be constructed with transparent walls to allow photographs to be taken of the fluid mixing. Heat flux 41 may be provided through the channel bed to simulate a hot computer chip. Liquid water may enter at one end 31 and flow through the rectangular channel 30, which is heated from below. A secondary fluid from reservoir 47 may be added to the water flow. The two may be either mixed upstream of the channel 30 and enter through the same inlet 31 via a valve 48, or the FC-72 may be first vaporized and injected into the channel downstream of the water inlet 31 via a valve 49. A general schematic of the apparatus and fluid flow setup is shown in FIG. 11.

Water may be pumped by pump 44 from a heated reservoir 42, through a constant temperature water bath 53, into the test channel 30. The volumetric flow of the water may be measured as it passes through a rotameter 43 before entering the channel. The FC-72 pump 45 may be set to deliver a predetermined amount of fluid prior to the start of the experiment. Volumetric flows may be measured before and after the experiment to verify the flow rate of the FC-72. Two scenarios for injecting the FC-72 may be used. In the first method, liquid FC-72 may be mixed with the water just before it enters the channel 30 and the two fluids enter together at inlet 31. In the second method, vaporized FC-72 may enter through a separate aperture 46 downstream of the water inlet 31. Heat may be applied at the channel 30 floor. Regardless of the method of injection, the FC-72 should be vaporized by the time it reaches the end of the channel 30. The two fluids may exit as separate streams at the end 32 of the channel. The water may discharge as a liquid through an opening in the channel 30 floor and go to a discharge tank 51 and the FC-72 may leave the channel as a vapor through the channel 30 roof. The FC-72 may go to a condensation tank 52 and then be condensed and recycled.

The apparatus may be a long rectangular channel 30. The walls consist of panes of 0.635 cm (0.25 in.) thick glass so that digital photographs may be taken of flow and mixing. Water is the main fluid, entering at a controlled volumetric flow rate. FC-72 is the secondary fluid. FC-72 may be injected in both vapor and liquid phase. For the current approach, uniform heat flux is desired, though the heating elements 35 are segmented and can provide hot-spot simulation. Steady heat flux is applied to the channel 30 bottom and the inlet and outlet temperatures, as well as the average wall temperatures along the channel 30 length, are measured.

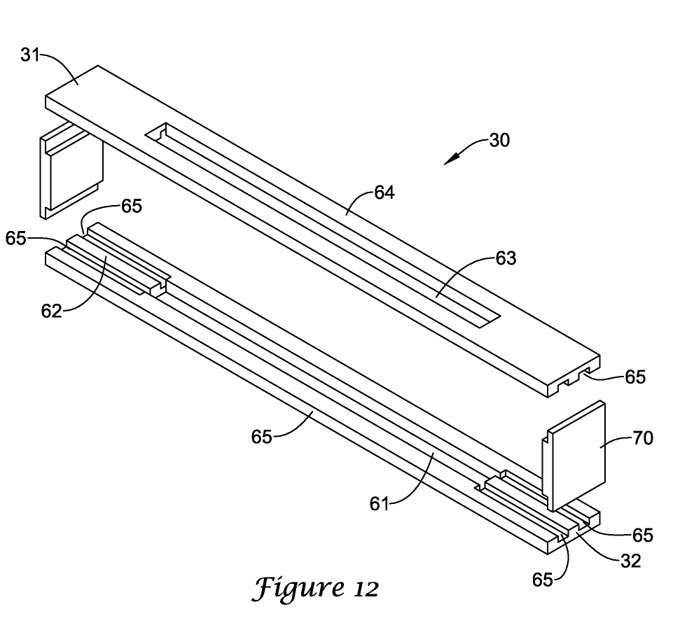

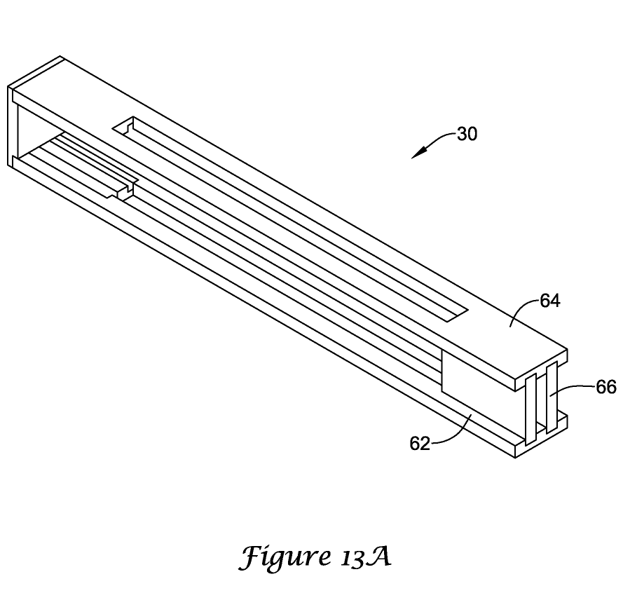

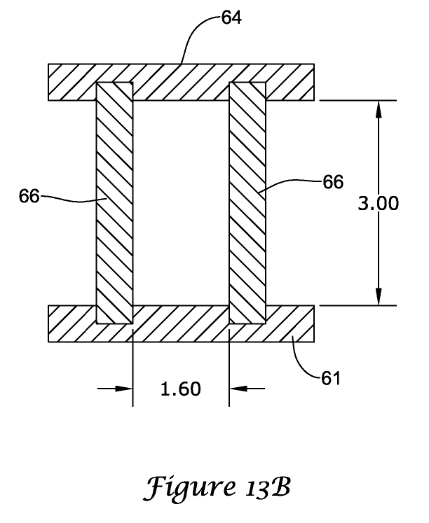

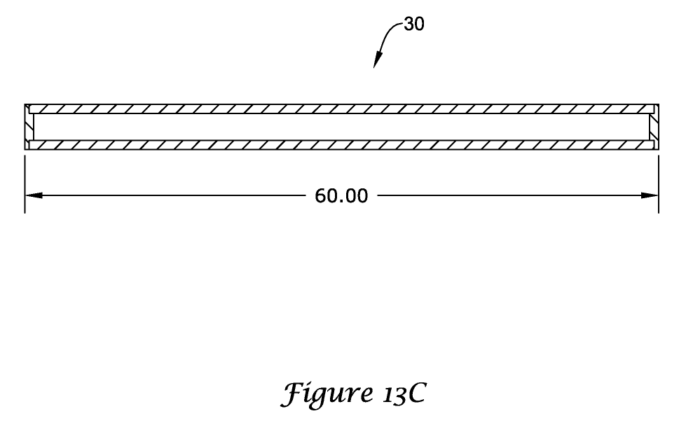

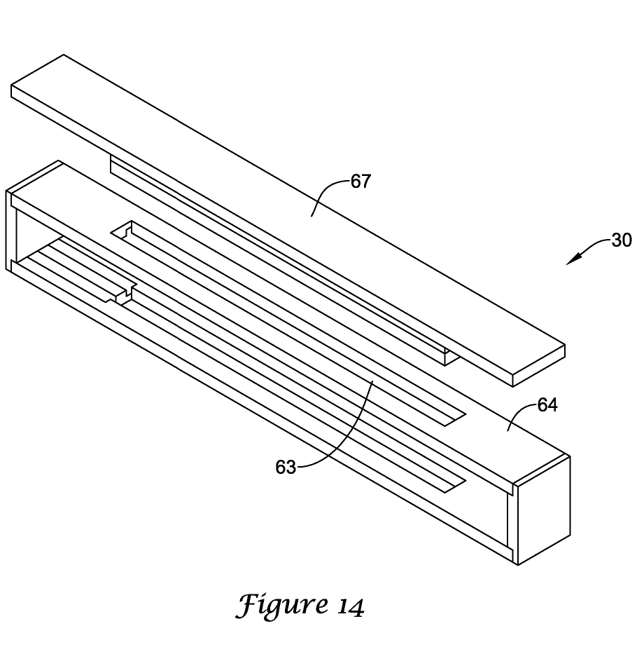

The structural components of the test channel may be machined from acrylic. This material is chosen because of its machinability and low cost. The components may be made from 1.27 cm (0.5 in.) thick acrylic stock material. An opening 61 in the bottom portion 62 of the rectangular channel 30 accepts a heater block. There is another opening 63 in the top portion 64 of the channel to provide access to the channel and to allow modifications to the channel aspect ratio. A removable cover 67 (FIG. 14) seals the opening in the top. Holes are drilled and threads may be tapped to accommodate fittings at the channel inlet 31 and outlet 32. FIG. 12 shows the basic structural components of the channel 30. Grooves 65 may be milled into the acrylic components. Theses grooves are 1.27 cm (0.5 in.) wide. The grooves 65 may accept two panes 66 (FIG. 13a) of glass. The two glass panes may be held together with Scotch™ brand permanent double sided tape. Each pane of glass is 152×7.62×0.635 cm (60×3×0.25 in.). The glass walls 66 may be glued into the grooves 65 using high temperature silicone sealant. An image of the channel 30 with glass walls 66 in place, along with basic channel dimensions, is shown in FIGS. 13a, 13b and 13c. The channel end 70 (FIG. 12) has been omitted to provide a view of the glass walls. The dimensions are in inches.

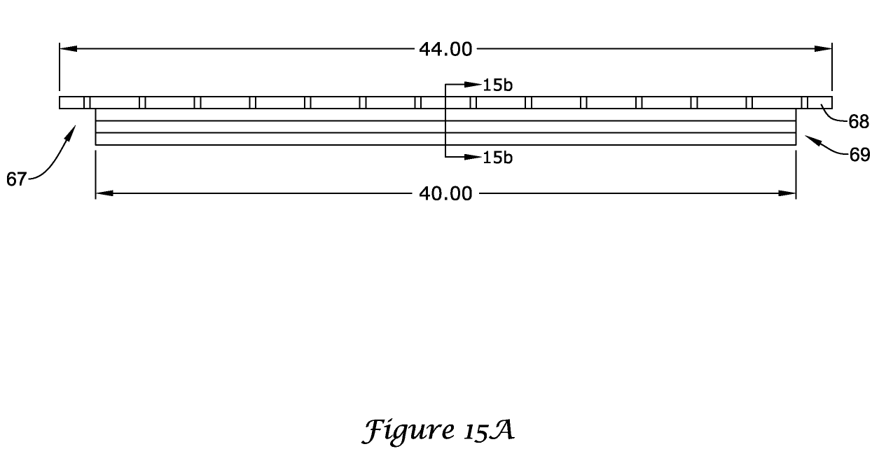

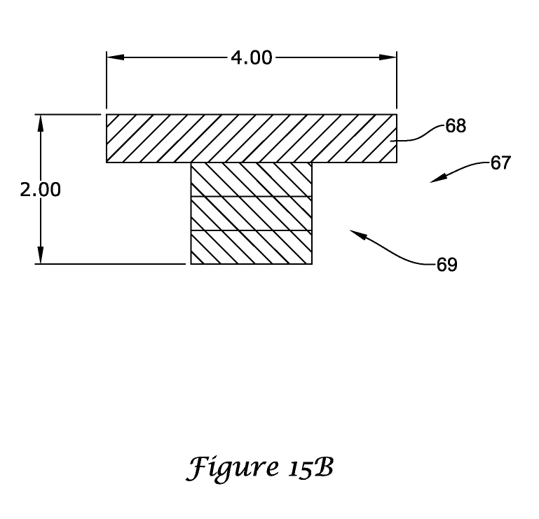

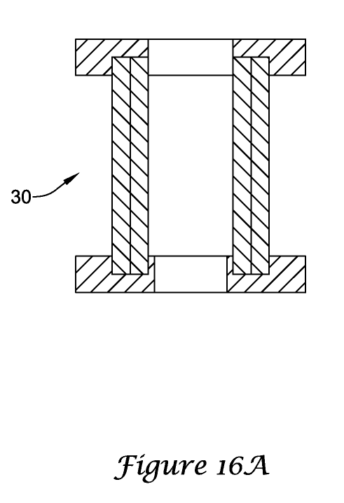

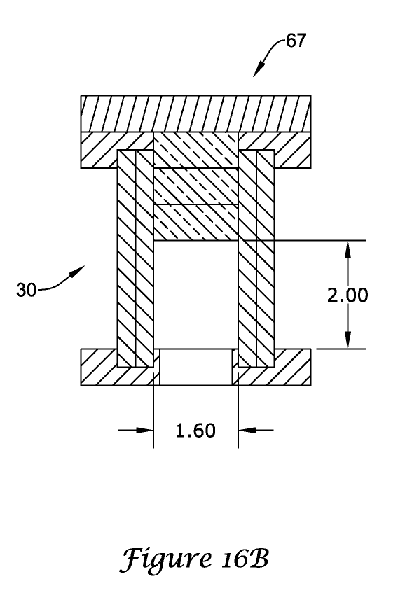

A gasket may be fitted between the cover 67 and the channel top. The cover is machined from 1.27 cm (0.5 in.) acrylic and consists of a flat plate 68 that bolts onto the channel top and three narrower spacers 69 (FIG. 15a). The spacers descend into the channel 30 providing the proper height-to-width aspect ratio. Each spacer 69 is 0.041×1.016×0.013 cm (1.6×40×0.5 in.). The number of spacers 69 may be altered to allow different aspect ratios. Images of the channel top are shown in FIGS. 14, 15a and 15b and 16a and 16b. FIGS. 14 shows how the removable cover 67 may fit into the channel roof 64 and be bolted in place. FIGS. 15a and 15b show length-wise and cross-section views of the removable cover 67, respectively. FIGS. 16a and 16b and 16c show a cross-section of the channel 30 without and with removable cover 67, respectively. The dimensions are in inches.

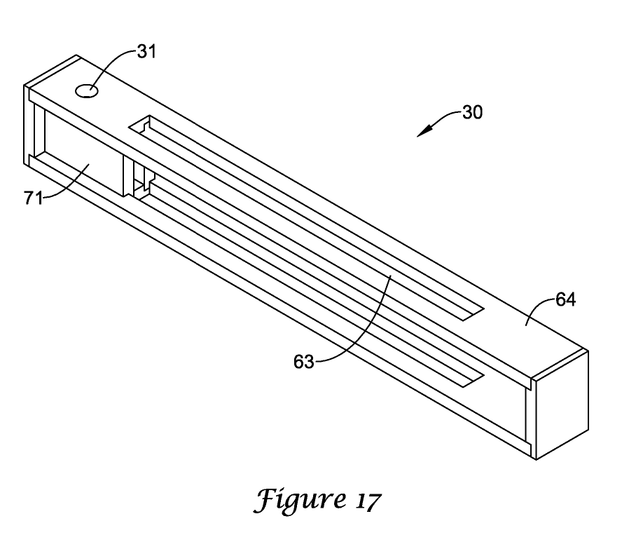

A flow conditioning or diffusion block, made up of numerous silicon beads, is placed just before the channel cover. FIG. 17 shows a diffusion block 71 consisting of numerous silicon beads held in a frame of acrylic and plastic mesh. The purpose of the diffusion block 71 is to calm or negate any turbulent effects from the water inlet. Items 80 may be insulation.

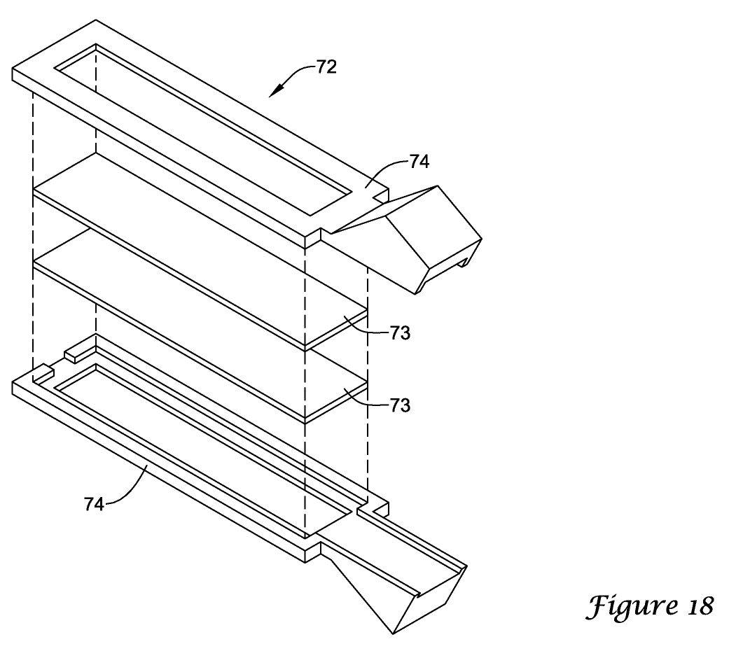

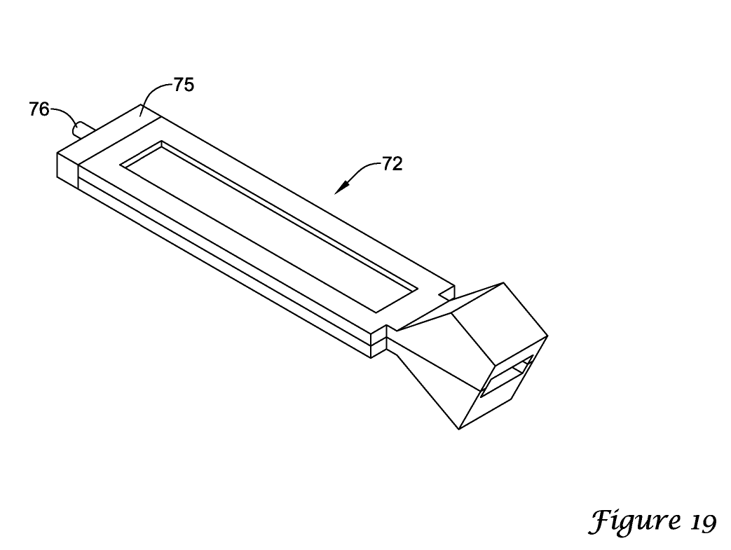

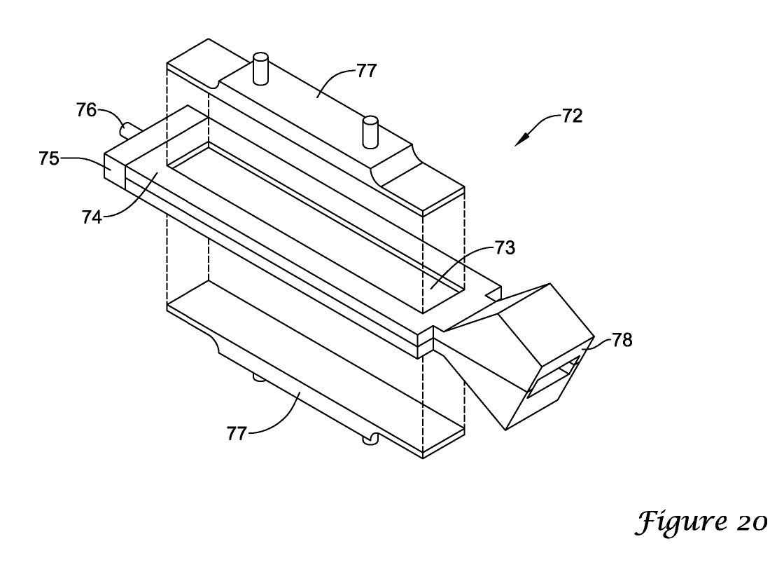

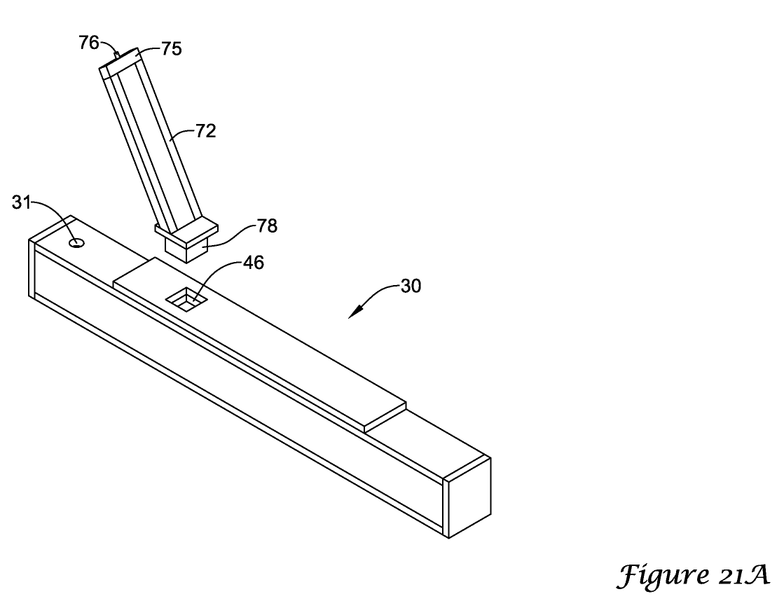

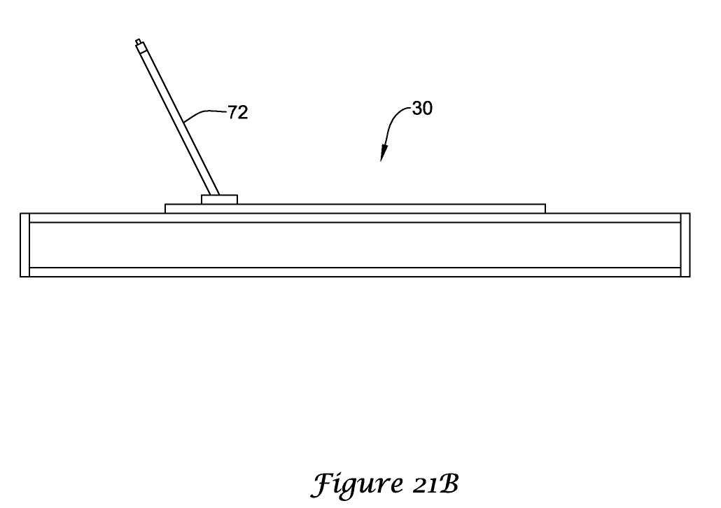

Two forms of injection may be noted. In the first form, the FC-72 may be delivered to the channel 30 in vapor form via a small rectangular duct 72 at input 46 (FIG. 11), oriented at 60 degrees from the horizontal. In the second form, the liquid FC-72 may be combined with the water in a simple tee-fitting upstream of the channel at input 31. The design for the FC-72 vapor delivery system is shown in FIGS. 18, 19, 20 and 21. FIG. 18 shows a FC-72 vaporizer consisting of two aluminum plates 73 fitted between acrylic components. When assembled, a rectangular 13.50×2.75×0.375 inch chamber is formed. FIG. 19 shows an acrylic cap 75 placed on the end of the assembly 72 and a Swagelok™ fitting 76 installed. Liquid FC-72 may be delivered through this fitting 76 into the rectangular hollow within the duct 72. FIG. 20 shows a Watlow™ strip heater 77 placed against the aluminum plate 73 on either side of the assembly 72. The FC-72 may be vaporized when heat is applied by heater 77. The vapor may then be forced out the rectangular exit 78. FIGS. 21a and 21b show an opening 46 machined into the channel 30 cover to accept the FC-72 vaporizer 72 and the vaporizer in place of the channel 30, respectively. Additional openings can be cut into the channel 30 cover to allow injection to occur at various locations. For the current approach, only one injection port 46 need be made.

Another injection approach may include mixing of FC-72 and water upstream of the channel inlet 31. This mixing approach was implemented, but the FC-72 fell straight the bottom of the inlet plenum and did not pass through the flow conditioning block 71. To remedy this, an injection tube to direct the water and FC-72 mix directly into the flow conditioning block was effected.

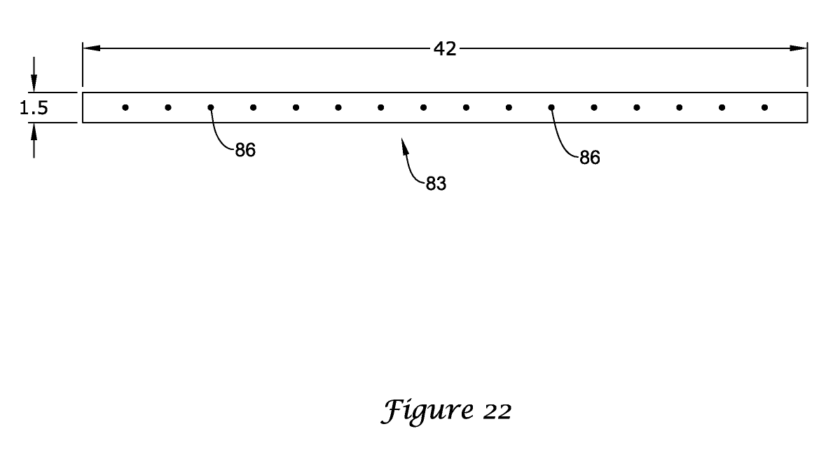

The hole 61 in the bottom of the channel 30 may be covered by a 0.0625 in. (0.159 cm) thick stainless steel plate 83. This plate may be glued into place with high temperature silicone sealant. The base plate 83 may be perforated with sixteen evenly spaced holes (FIG. 22). A thermocouple 86 may be glued into each hole with thermally conductive epoxy. Care may be taken to ensure that the thermocouple junctions 86 are flush with the surface of the plate 83 and that they are adequately coated with epoxy to guarantee sufficient electrical insulation. The thermocouples may be made from 30 gauge chromel and constantan wire (Type E). This type of thermocouple may be chosen because it appears to produce the highest voltage for a given temperature. In addition, the thermal conductivity of Type E wire appears to be the lowest of any commonly available thermocouple type, thus reducing fin-effects.

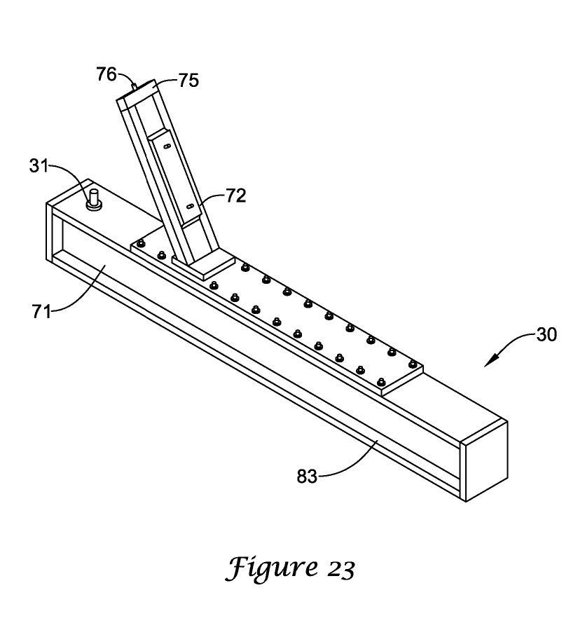

FIGS. 22 and 23 show the positioning of the thermocouples 86 within the stainless-steel base plate 83 and the placement of the plate within the channel 30. FIG. 22 shows sixteen Type E thermocouples embedded in holes in the stainless-steel base plate. Positions of the hole and corresponding thermocouples may be measured from the left end of the plate 83. Plate 83 may be 42 inches long and 1.5 inches wide. An example placement of thermocouples 86 starting from the left end may start at 2.35 inches and be at every 2.5 inches thereafter to the 16th thermocouple. The dimensions are in inches. FIG. 23 shows the base plate 83 fitted into the channel 30. Thermocouple leads extend of the bottom of the channel 30. The dimensions are in inches.

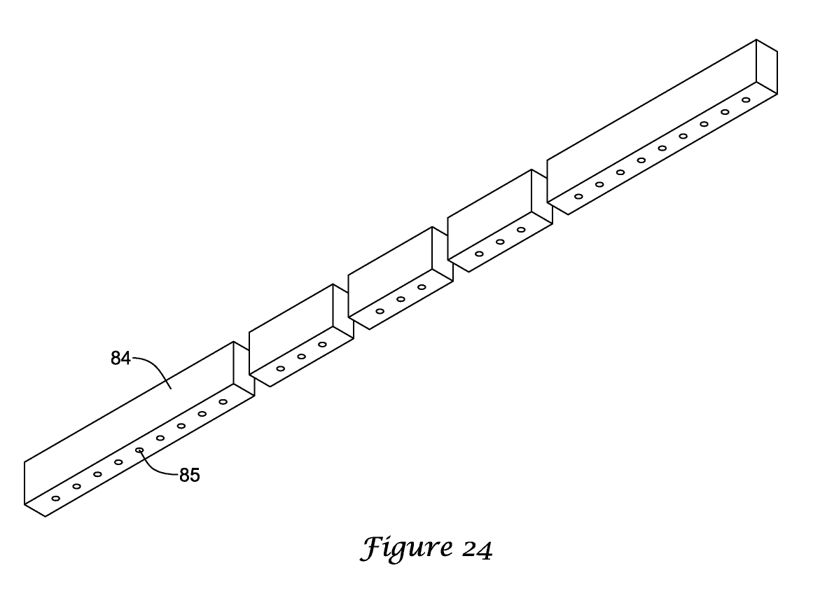

The heater blocks may be installed under the stainless-steel base plate 83. FIG. 24 presents a view of five individual heater blocks 84 with twenty-seven cartridge heaters 85 are installed. A layer of thermally conductive grease is applied to the top of each heater block 84 and it is pressed flush against the stainless-steel plate 83 in the channel 30 floor. Grooves 88 may be machined into the heater blocks 84 to provide clearance for each thermocouple 86. Each block 84 may be machined from a bar of aluminum, with holes milled to accommodate cartridge heaters 85. The five separate heater blocks 84 are secured together with a layer of high temperature RTV silicon. This allows each of the blocks 84 to be individually turned on or off, and limits thermal conduction to neighboring blocks 84. This design may provide the possibility of hot-spot testing in the channel 30.

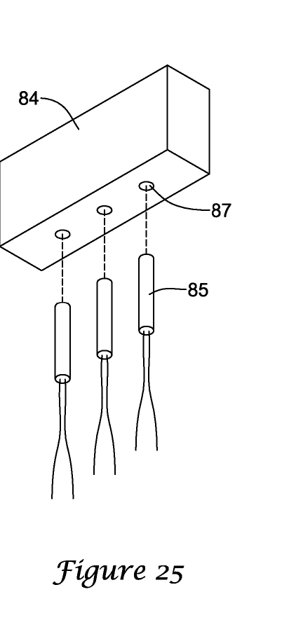

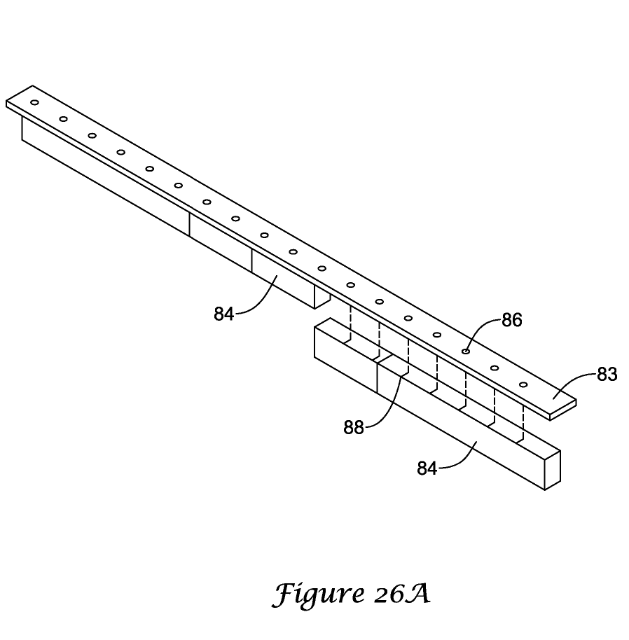

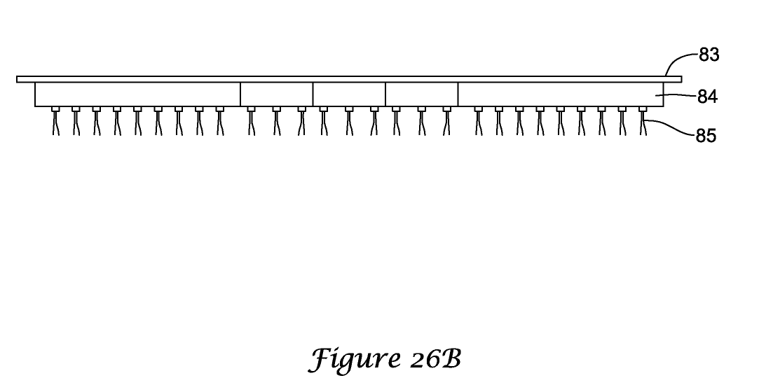

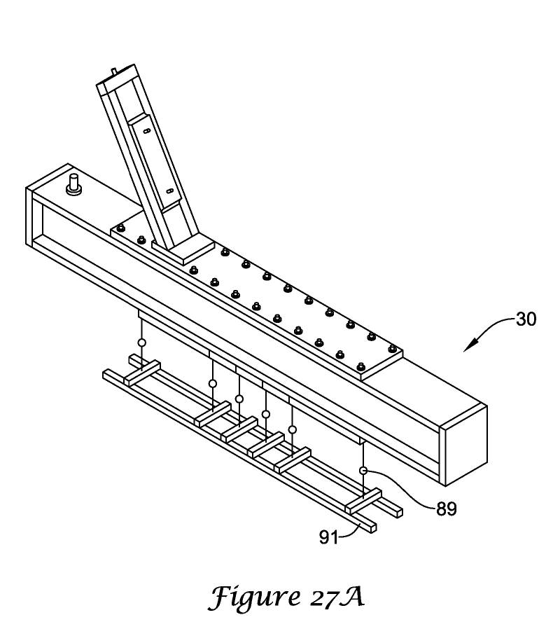

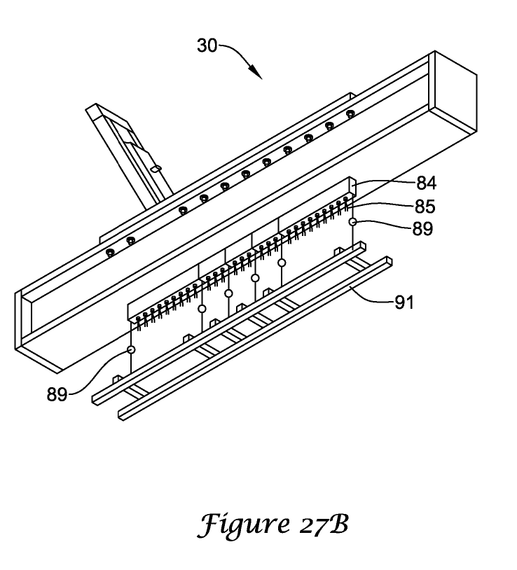

Thermally conductive grease may be applied to the surfaces of the holes and a cartridge heater 85 is inserted into each hole or opening 87 (FIG. 25) of the heater block 84. FIGS. 26a and 26b show grooves 88 milled into the top of each heater block 84 to provide clearance for the thermocouples 86. The heater blocks 84 may be pressed against the stainless-steel channel floor plate 83. FIGS. 27a and 27b show several views of ceramic discs 89 and a framework 91 of Unistrut™ used to press the heater blocks 84 into place.

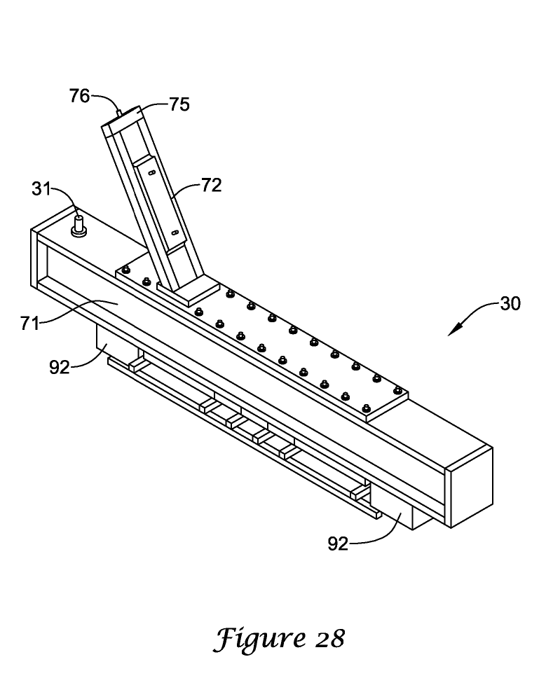

After all of the heaters 85 are installed, a hammer and a screwdriver may be used to deliver a sharp blow to the bottom of the heater block 84 near each opening 87. This may cause the aluminum of the heater block 84 to deform slightly, and served to crimp each heater 85 in place. The framework 91 of Unistrut™ is used to clamp the heater blocks 84 against the stainless-steel channel bottom plate 83. Ceramic discs 89 may be placed between the heater blocks 84 and the frame 91 to limit conduction. A thin layer of thermally conductive grease is applied between the heater blocks 84 and the stainless-steel plate 83. Polystyrene insulation 92 may be installed at the ends of the channel 30. The heater blocks 84 may be covered with high temperature fiberglass insulation to minimize heat losses. FIG. 28 provides a view of this final assembly. The fiberglass insulation is not shown.

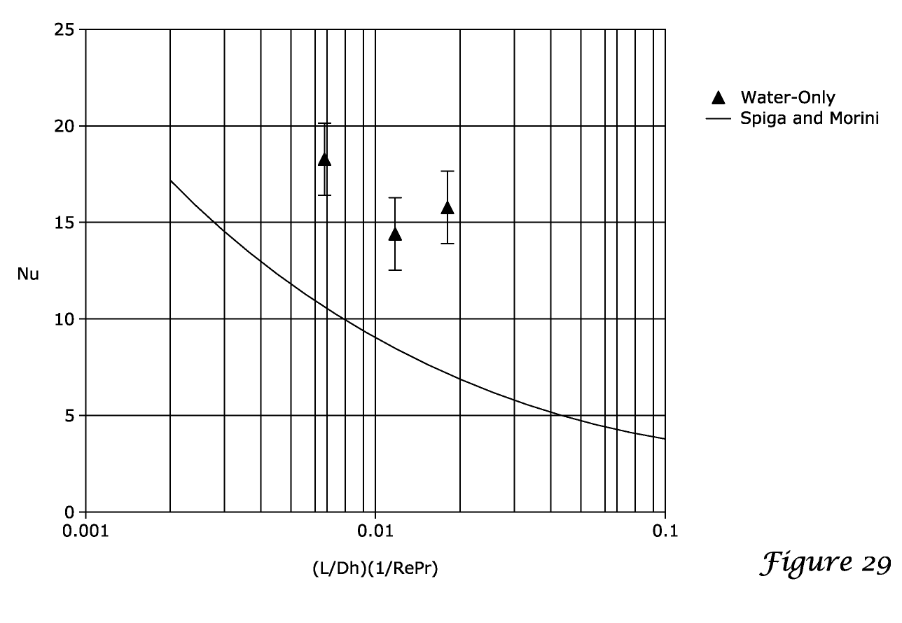

Results may be noted. The apparatus 30 is intended to examine thermally and hydrodynamically developing flow in a rectangular channel. An analytical solution for this problem may be taken from the literature (e.g., Spiga, M., et al., “The Thermal Entrance Length Problem for Slug Flow in rectangular Ducts”, ASME Journal of Heat Transfer, 1996, v. 118, n. 4, November, pp. 979-982) and may be used as a comparison. The water-only experiments are performed to determine whether results can be obtained that are similar to conventional results that may occur. FIG. 29 shows a graph of water-only flow experiments 1, 2 and 3 (see FIG. 2b). The curve is an analytical solution provided by Spiga et al. which may be regarded as valid for thermally and hydrodynamically developing flow in rectangular ducts. The graph reveals data in terms of Nu versus (LDh)(1/RePr).

Results for water-only flow indicate that the apparatus yields Nusselt numbers that are higher than predicted by the analytical solution. This is because the modifications to the water inlet conditions (as shown in FIG. 22) have resulted in a flow that is non-uniform. Fluid flow conditions in the test channel are not the same as those in the analytical case that is intended to serve as a comparison. Even so, Nusselt number results show the same trend as those that may be conventionally predicted. The mixing effects at the channel 30 inlet 31 appear to be the cause of the higher Nusselt numbers.

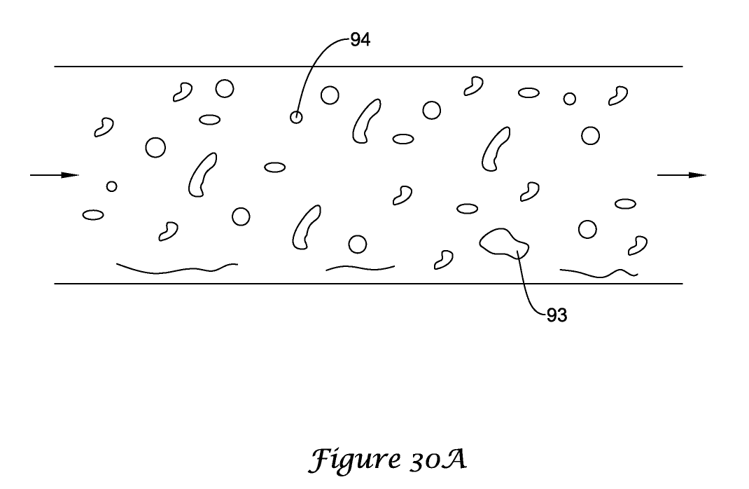

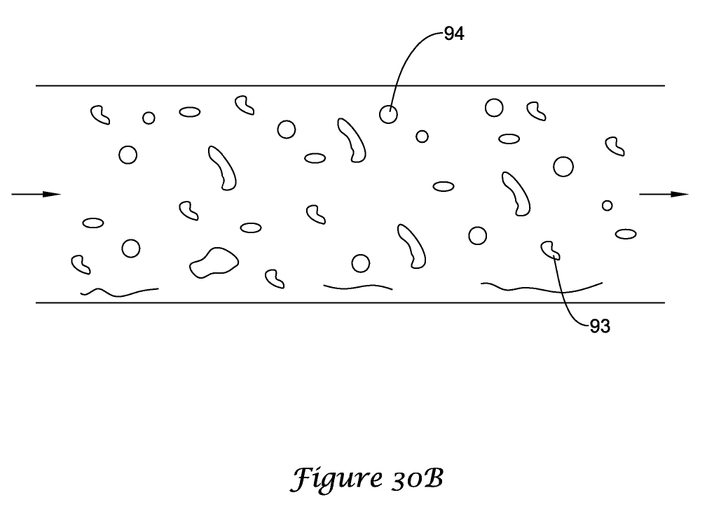

FIG. 30a is a diagram of a flow left to right through a channel showing vaporized FC72 items 93 and condensed bubbles 94 of a two-liquid “three-phase” flow. The “three phase” here means FC72 bubble, FC72 liquid droplet and water mixing together in the flow. FIG. 30b is another depiction of the flow in FIG. 30a. The activity shown in these Figures is described herein.

The arbitrary geometry of the rectangular injection nozzle 72 may provide too great of an opening. A smaller opening might result in a more focused FC-72 vapor stream.

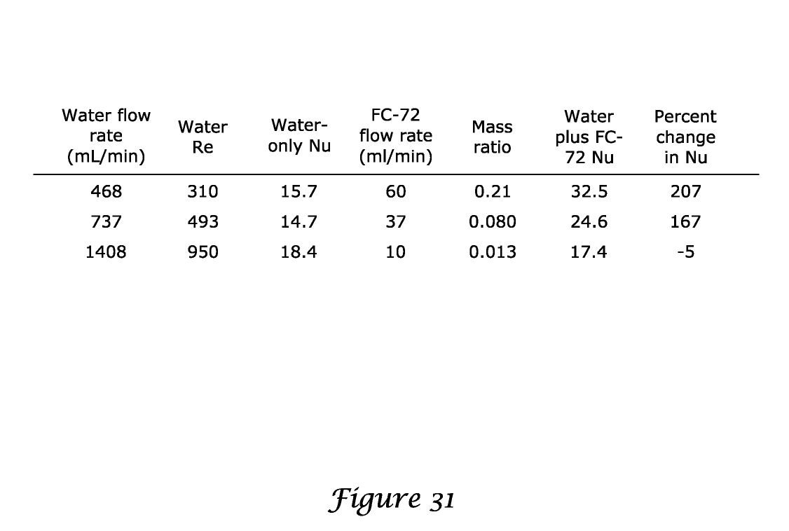

Results for the case where FC-72 and water are mixed, for instance, in the tee-fitting at input 31 upstream of the channel 30, are summarized in a table of FIG. 31. After passing through the conditioning block 71, the FC-72 may settle rapidly to the bottom of the channel 30. Upon contact with the hot channel bed, the FC-72 boils and vapor bubbles rise into the water stream. The vaporized FC-72 condenses in the water, which is at temperatures below the saturation temperature of FC 72. The condensed FC-72 sinks back to the channel 30 floor, and the process repeats. The water temperature at the channel outlet 32 is above the boiling point of FC-72. Near the channel 30 exit 32, the FC-72 rises and forms a vapor layer. This process may be of experiment 7 with m₂/m₁=0.21 and water flow Re=310.

FC-72 water may be just after the flow conditioning block. The FC-72 settles to the channel floor. Boiling occurs when the FC-72 contacts the hot surface. The water Reynolds number is 300 and m²/m¹=0.21. The flowing water may carry the FC-72 vapor bubbles downstream. The bubbles condense in the sub-cooled water stream and sink back to the channel 30 floor. The larger bubbles are vaporized FC-72 rising to of the channel and the small bubbles are condensed FC-72 sinking to the bottom. Further downstream, the FC-72 forms pools on the channel 30 floor. The vaporizing/condensing cycle may continue. As the fluid moves toward the channel 30 exit 32, the water temperature approaches the boiling point of FC-72. Near the channel outlet, a definite layer of vaporized FC-72 may be seen at the top of the channel 30.

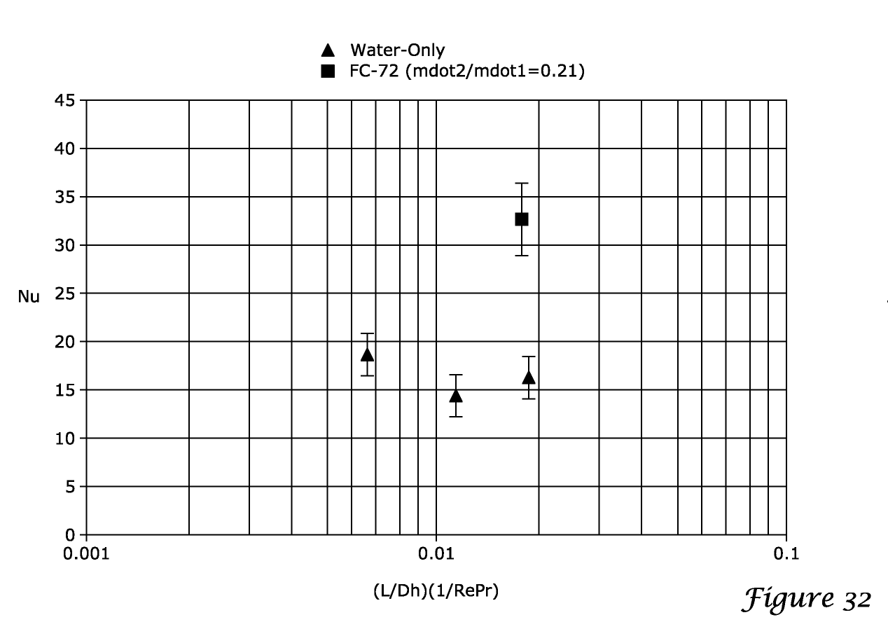

The graphs of FIGS. 32, 33 and 34 reveal data for experiments 7, 8 and 9, with ratios of mdot2/mdot1 equal to 0.21, 0.08 and 0.013, respectively, in terms of Nu versus (LDh)(1/RePr). FIG. 32 shows a graph with results of the experiment 7. The heat flux into the channel is 7774 W/m² and the Reynolds number for the water flow is 310. The volumetric flow rate of the water and FC-72 is 468 mL/min and 60 mL/min, respectively. This Figure presents Nusselt number results for the experiment (the same one as in the preceding Figures). The combination of high injection rate of FC-72 and low water Reynolds number has resulted in a Nusselt number that is 207 percent of the water-only flow.

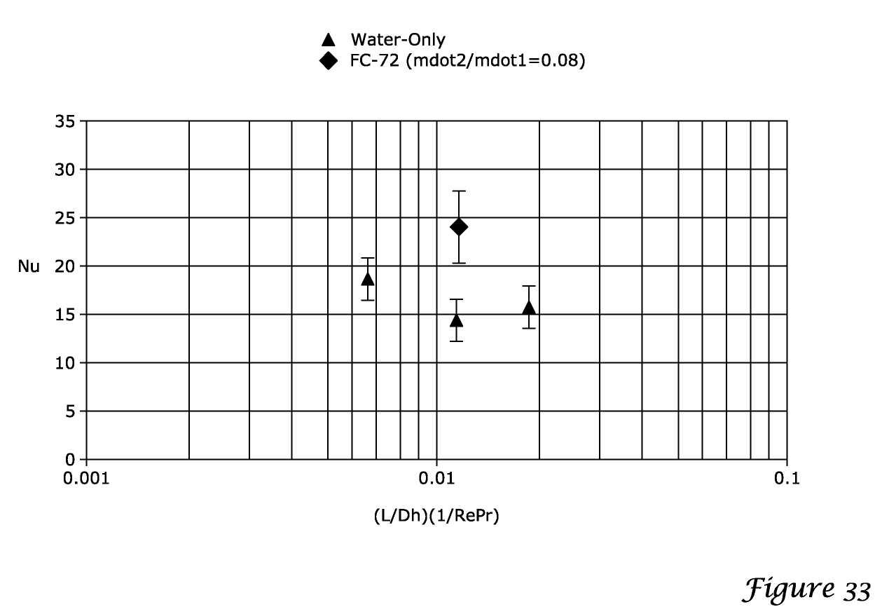

FIG. 33 is a graph that shows Nusselt number results from experiment 8 compared to water-only flow. The heat flux into the channel is 7396 W/m² and the Reynolds number for the water flow is 468. Again, the same method of injection is used as in the previous Figure. The addition of FC-72 resulted in a Nusselt number that is 167 percent that of water-only flow.

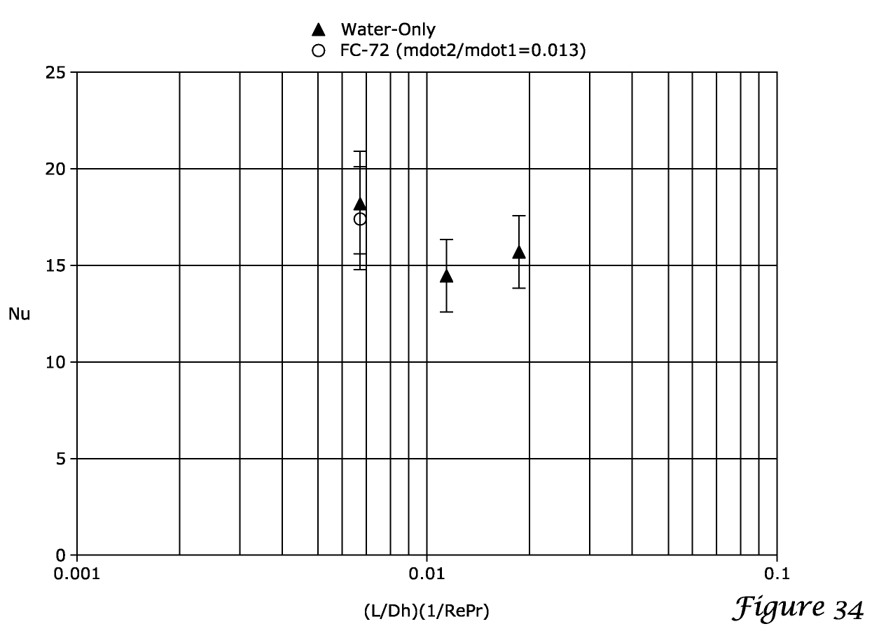

FIG. 34 is a graph showing Nusselt number results from experiment 9 compared to water-only flow. The heat flux into the channel is 3996 W/m² and the Reynolds number for the water flow is 1000. The volumetric flow rate of the water and FC-72 is 1408 mL/min and 10 mL/min, respectfully. This has the same injection method as the previous Figure, but the addition of FC-72 in such small amounts does not cause any increase in the Nusselt number compared to water-only flow.

A large test channel 30 apparatus was built to emulate flow in a micro channel 12 (FIG. 3b). The experiment discussed shows that the introduction of FC-72 into the coolant stream does enhance cooling. The overall heat transfer coefficient for water-only flow and water/FC-72 flow is determined and compared.

The flow conditions in the test channel 30 apparatus might not precisely mimic those found in the micro-channel 12. Forced convection may dominate in the micro-channel 12, while free convection appears as the mechanism of heat transfer in the large channel 30. In addition, the method of injecting the water and liquid FC-72 mix into the channel 30 may result in non-plug flow.

Mixing the FC-72 and water upstream of the channel 30 inlet 31 and injecting them into the channel 30 together does result in heat transfer gains. Higher ratios of FC-72/water results in increased Nusselt numbers compared to water-only flow. Based on the experiments, it may be concluded that the use of a two fluid cooling stream (water and FC-72) offers significant cooling advantages when compared to water-only flow in the channel 30 test apparatus. Nusselt numbers with FC-72 injection appear to be up to about 207 percent compared to those of water-only flow with similar injection conditions.

Tests with three-times scale and one-time scale devices, like the 100-times scale device tests noted herein, have been performed with similar results. The one-time scale device is of the chip scale and similar in size as that of an IC chip or MEMS device. Tests of the scaled-up devices of 100 times and three times provided verifications of the one-time scale devices. These tests may also be viewed as a scaled-up verification of smaller scale device such as nano-scale devices.

Using a two-liquid mixture, tests have shown that heat transfer enhancements of about 35 to 107 percent can be achieved compared to the single phase developing water flow. A separation of the tests show about 107 percent attained for 100-times scale devices, 40 to 83 percent for three-times scale devices, and 35 percent for the one-time or actual scale devices. Testing of those devices has not been extensive. Reasons for the differences may include different bubble, surface tension and buoyancy effects at different scales, which have not been included in the general heat equations. These test devices are simplified in that they do not have optimal conditions and design, for example, optimal mixing, optimal injection enhancement, and so forth. The mass ratio of FC in the two-liquid mixture has a strong influence on the heat transfer enhancement. This ratio as used herein may be subject to significant improvement.

For aluminum three-time scale channels, water only results appear to agree with conventional results for laminar single-phase convection. Initially, when liquid FC72 and water were mixed upstream of the channel inlet, local heat transfer coefficients showed improvements over single-phase water flow. The aluminum surface was significantly degraded within two weeks of initial testing. This surface degradation resulted in Nu lower than the theoretical values for corresponding Re. However, results of water versus water and FC72 mixtures may still be compared for the same experimental run, with an indication of heat transfer enhancement. A switch to a copper device was made for surface stability.

When air was injected from above through fifteen holes along each channel of the aluminum device, heat transfer was enhanced and a wall temperature drop was seen along the channels. Vapor injection from above at low Re also showed an enhancement. Overall, the best cases showed increases of about 40 and 83 percent. The worst case appeared to show a slight decrease in the heat transfer, due to too much FC72. In general, an enhancement of more than ten percent was seen.

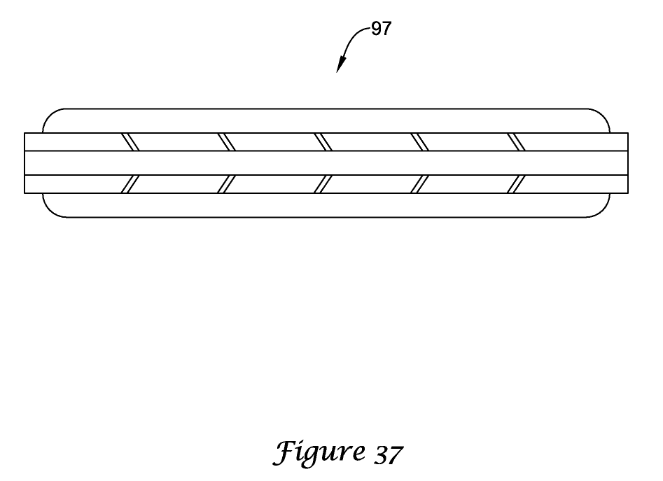

For copper channels (three-time or one time scale), single-phase water results appeared to agree with conventional results. As to the three-times scale device, for a flow of FC72 and water mixed upstream of the channel sections, a heat transfer enhancement was observed. When FC72 is added through slots at 45 degrees in the side wall of a single channel, as illustrated in FIG. 37, enhancements were seen over single phase water results. When liquid FC72 was added from above through small openings, a heat transfer enhancement was achieved. Testing indicated that Nu=15 can be achieved at high Re using the copper channels.

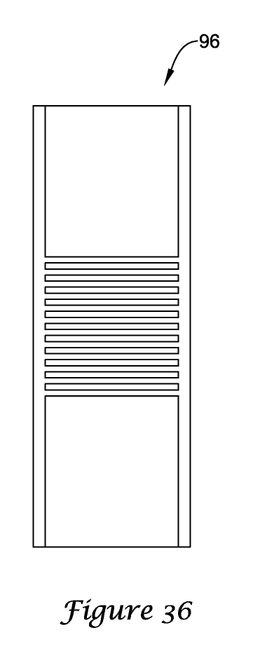

For a one-time scale device, as illustrated in FIG. 36, a heat transfer enhancement appeared to be achieved when water and FC72 were mixed upstream of the channels. A difference calculation method would seem to show an enhancement over single-phase water.

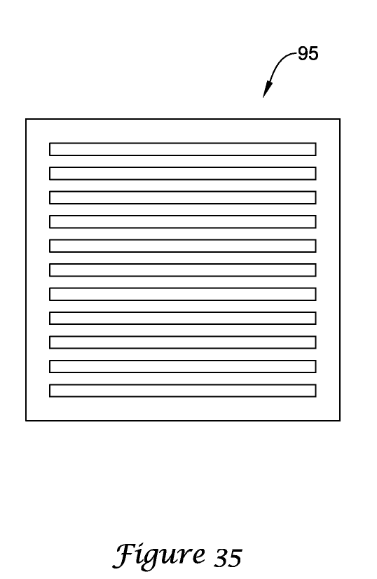

FIGS. 35 and 36 show examples of a three-times scale copper device 95 and a one-time scale copper device 96, respectively. FIG. 37 shows a three-times scale copper device 97 with 45 degree side injection.

The tests noted herein are of a preliminary nature. Extensive testing has not been done at this time.

In the present specification, some of the matter may be of a hypothetical or prophetic nature although stated in another manner or tense.

Although the invention has been described with respect to at least one illustrative example, many variations and modifications will become apparent to those skilled in the art upon reading the present specification. It is therefore the intention that the appended claims be interpreted as broadly as possible in view of the prior art to include all such variations and modifications.

What is claimed is:

1. A system for cooling comprising:
at least one channel; and
multiple fluids; and
wherein the at least one channel is for containing a movement of the multiple fluids for cooling.

2. The system of claim 1, wherein:
at least one fluid is immiscible relative to at least one other fluid; and
at least one fluid has a boiling point lower than a set maximum temperature.

3. The system of claim 1, wherein:
at least one fluid is miscible relative to at least one other fluid; and
at least one fluid has a boiling point lower than a set maximum temperature at one atmosphere.

4. The system of claim 1, wherein:
a first fluid of the multiple fluids has a first boiling point;
a second fluid of the multiple fluids has a second boiling point;
the first boiling point is greater than the second boiling point; and
an operating temperature of the at least one channel is between the first and second boiling points.

5. The system of claim 4, wherein:
the first fluid is in a liquid phase at a time of entry into the at least one channel; and
the second fluid is in a gas phase at a time of entry into the at least one channel.

6. The system of claim 4, wherein:
the first liquid is water; and
the second liquid is a halogenated compound.

7. The system of claim 4, wherein:
the first fluid is water; and
the second fluid is a fluorinated compound.

8. The system of claim 7, wherein the second fluid is at least one of a group consisting of at least FC-72, FC-84, FC-77, FC-40, FC-43, Genetron 245FA, and other fluorocarbon coolants.

9. The system of claim 8, wherein the second fluid is FC-72.

10. A system for cooling a device comprising:
a heat sink for thermal contact with a device; and
wherein:
the heat sink comprises:
at least one channel;
a first fluid for flowing through the channel; and
a second fluid for flowing through the channel;
the first fluid has a boiling point higher than the desired cooled-to a maximum allowable temperature of the device; and
the second fluid has a boiling point lower than the desired cooled-to temperature of the device.

11. The system of claim 10, wherein the desired cooled to temperature has a range between 45 degrees C. and 95 degrees C.

12. The system of claim 10, wherein the first and second fluids are immiscible.

13. The system of claim 10, wherein:
the at least one channel has at least one inlet; and
the at least one inlet is for entry of a fluid.

14. The system of claim 13, wherein the fluid may be one or more of mixed liquids, mixed liquid and vapor.

15. The system of claim 13, wherein:
the one or more inlets are multiple inlets; and
the multiple inlets comprise:
one main inlet for a first fluid; and
a plurality of small inlets for a second fluid.

16. The system of claim 15, wherein:
the first fluid is water; and
the second fluid is a cooling fluid.

17. The system of claim 10, wherein:
the at least one channel has an inlet; and
the inlet is for entry of the first and second fluids.

18. A fluid for cooling comprising:
a first component having a first boiling point; and
a second component having a second boiling point; and
wherein the first boiling point is greater than the second boiling point.

19. The fluid of claim 18, wherein the first component and the second component are miscible.

20. The fluid of claim 18, wherein the first component and the second component are immiscible.

21. The fluid of claim 20, wherein:
the first component is water; and
the second component is a fluid having a boiling point less than 95 degrees Celsius.

22. The fluid of claim 21, wherein:
the fluid for cooling is moved through a conveyance structure;
the first and second components are moved into the conveyance structure as liquid or liquid-vapor mixture; and
the conveyance structure becomes a cooler with the first and second fluids being moved through the conveyance structure.

23. The fluid of claim 22, wherein the conveyance structure is a plurality of micro/mini channels.

24. The fluid of claim 22, wherein the conveyance structure is a plurality of meso or large-scale channels.

25. The fluid of claim 22, wherein the conveyance structure is a plurality of nano channels.

26. The fluid of claim 22, wherein the conveyance structure is a porous material.

27. The fluid of claim 22, wherein at least one wall of the conveyance structure is a porous material.

28. A method for cooling comprising:
providing a coolant having first and second components; and
contacting a mechanism to be cooled with the coolant at an operating temperature; and
wherein:
the first component has a boiling point above the operating temperature; and
the second component has a boiling point below the operating temperature.

29. The method of claim 28, wherein the components are immiscible.

30. The method of claim 28, wherein the components are miscible.

31. The method of claim 29, further comprising injecting the second component as a vapor into a fluid flow of the first component.

32. The method of claim 31, further comprising contacting the coolant with a porous material or capillary channels to improve a vaporization of the second component.
